(19) United States
(12) Patent Application Publication
(10) Pub. No.: US 2025/0377424 A1
(43) Pub. Date: Dec. 11, 2025

(54) Wireless Integrated Sensing Device For Simultaneous EEG And MRI Detection

(71) Applicant: Board of Trustees of Michigan State University, East Lansing, MI (US)

(72) Inventor: Chunqi QIAN, Okemos, MI (US)

(21) Appl. No.: 19/214,374

(22) Filed: May 21, 2025

Related U.S. Application Data
(60) Provisional application No. 63/656,762, filed on Jun. 6, 2024.

(51) Int. Cl. G01R 33/32; G01R 33/34; G01R 33/48; H02J 50/00

(52) U.S. Cl. CPC G01R 33/323; G01R 33/34; G01R 33/4806; H02J 50/005; H02J 2310/23

(57) ABSTRACT

A detector circuit includes a parametric resonator circuit comprising a first varactor and a second varactor disposed in a loop. The parametric resonator has a conductor disposed between the first varactor and the second varactor. The detector circuit further includes a voltage sensing resonator circuit aligned on the parametric resonator circuit so that at least a first portion of the resonator circuit is disposed in the loop and a second portion is disposed outside the loop in an axial view.

### CROSS-REFERENCE TO RELATED APPLICATION

This application claims the benefit of U.S. Provisional Application No. 63/656,762, filed on Jun. 6, 2024. The entire disclosure of the above application is incorporated herein by reference.

### GOVERNMENT FUNDING

This invention was made with government support under NIH 1RF 1NS128611 awarded by the National Institute of Health and NSF 2144138 awarded by the National Science Foundation. The government has certain rights in the invention.

### FIELD

The present disclosure relates generally to wirelessly powered sensors, and, more particularly, to a system and method for wirelessly powering a signals suitable for in vivo applications.

### BACKGROUND

This section provides background information related to the present disclosure which is not necessarily prior art.

Linking functional perspectives across scales from the cellular level to the circuit/systems level remains a major challenge in brain research. Functional MRI has been developed to indirectly map neuronal activity across the entire brain, based on vascular hemodynamics (e.g., blood flow, blood volume, or blood oxygenation levels) which contribute to fMRI signals. To link neuronal activity with vascular hemodynamics, simultaneous electroencephalogram (EEG) and fMRI have also been proposed to monitor both neuronal and hemodynamic activities helping to correlate these two important components that regulate neurovascular coupling and decoupling events in healthy or diseased brains. In epilepsy research, simultaneous EEG-fMRI can localize the epileptogenic regions. For perception study, EEG-fMRI can correlate brain regions with salient BOLD responses to EEG signals with distinct neural frequency bands involved in perception. For brains in resting state, EEG-fMRI can observe functional network reorganization on multiple spatiotemporal scales, thus identifying the metastable brain states that are distinguishable by their EEG rhythms and that are associated with default brain network. During sleep, EEG-fMRI can monitor sleep stages and follow changes in the default-mode network through successive stages, thus demonstrating the relationship between brain activation time and cognitive ability variation. To study cognitive control, a variety of EEG components can be used as regressors in fMRI analysis, helping to dissociate the respective roles of different brain networks.

Despite its steady progress over the past two decades, simultaneous EEG/fMRI is still technically challenging. The wired connections required for conventional electrodes collect electromagnetic interference signals, especially during the MR excitation pulses and switching magnetic field gradients. These major artifacts can often saturate preamplifiers that are designed for weak EEG signals, making the recorded EEG signals hard to extract from the noisy background. Although these issues can partially be addressed during post-processing, reliable recovery of weak EEG signals from the much stronger background interference requires concurrent use of high-gain preamplifiers and high-speed Analog Digital Converters with large dynamic range, leading to bulky and complex hardware with additional safety concerns. An alternative way for artifact reduction is to synchronize the EEG apparatus with the MR-scanner, so that EEG signals can be acquired only during the MRI acquisition window when the excitation pulse is switched off and the encoding gradient remains stable. However, this approach requires precise synchronization with the MR-scanner and prior knowledge about the pulse sequence, which is difficult to implement. Recently, wireless electrophysiology transducers have been developed to utilize on-board gradient sensors and micro-controllers for dynamically identifying the proper acquisition window with stable magnetic field gradient, enabling the synchronically acquired EEG signals to be encoded onto the wireless carrier wave and detected by a standard MRI coil. Promising as it is, this approach requires on-board microcontrollers and dedicated RF transmitters that are powered by sizable internal batteries, making them hard to miniaturize for interventional and implantable applications.

### SUMMARY

This section provides a general summary of the disclosure, and is not a comprehensive disclosure of its full scope or all of its features.

To overcome the above-mentioned limitations, a wirelessly powered oscillator that can simultaneously encode fMRI and EEG signals is set forth. The present system is a major improvement from the known Wireless Amplified NMR Detectors (WAND) that were initially developed for MRI sensitivity enhancement in deep-lying tissues. In the present system, when the wireless pumping power is increased beyond an oscillation threshold, the WAND becomes an oscillator that can directly convert wirelessly provided pumping power into sustained oscillation currents near the resonant frequency of the circuit. Unlike conventional voltage-controlled oscillators that can only encode low-frequency signals or down-converted high-frequency signals, the wireless oscillator can utilize circuit nonlinearity to combine down conversion and frequency encoding of MRI signals into a single stage. Because the circuit oscillation can also be modulated by low-frequency bias voltages applied on its nonlinear components, low-frequency neuronal signals are also encoded onto the same FM-modulated carrier wave, but on a distinct sideband from the simultaneously encoded high-frequency MRI signals.

The oscillation carrier wave can be continuously detected by a standard MRI coil and recorded by the MR scanner over the entire duration of MR acquisition windows, in the same way as how conventional MR signals are detected. Without the need for dedicated gradient sensors or synchronization apparatus, the oscillator can reliably encode MRI and EEG signals, even during gradient switching periods. Since the down-converted MRI signals and neuronal signals exhibit different frequency separations from the carrier center, the signals may be distinguished by high-pass and low-pass filtering following frequency demodulation. As a result, no dedicated hardware is needed to synchronize MRI and EEG detection. The pumping power can reduce the effective resistance of the circuit and increase its quality factor by ˜39000 fold, making the oscillation frequency very sensitive to small modulation voltages, thus obviating the need for high-power preamplifiers or digitizers that were traditionally required to recover subtle neuronal signals from the artifactual background. Without the need for ADC converters or microprocessors, our device has a compact design that is easy to implement, incurring a minimum fabrication cost. When the oscillator is mounted on a rodent's head for optogenetically evoked fMRI, only a few milliwatts of wireless power is required to activate the transducer, inducing negligible heating effects.

The voltage sensing resonator herein utilizes a transistor, rather than varactor for better efficiency. It has a butterfly shaped structure to reduce its perturbation by MRI excitation pulses. Moreover, the voltage sensing resonator interacts with the circular mode of the parametric resonator that is tuned well above the MRI excitation frequency, thus minimizing the whole circuit's perturbation by MRI excitation pulses.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a first example of a parametric resonator having a circular-shaped current flow.

FIG. 1B is the voltage sensing resonator of FIG. 1 having a butterfly-shaped current flow.

FIG. 1C is a diagrammatic view of a voltage sensing resonator.

FIG. 1D is a diagrammatic view of the WISDEM detector having the parametric resonator and the voltage sensing resonator.

FIG. 1E is a top view of the circuit of FIG. 1D.

FIG. 1F is a plot of frequency to voltage ratio at different voltages and inset plot at about 100 MHz.

FIG. 1G is the parametric resonator of FIG. 1A with a loop enhancer circuit.

FIG. 1H is an alternate design of a parametric resonator with one resonating frequency.

FIG. 1I an alternate design of a parametric resonator with two separate circuits and a common enhancer circuit around both.

FIG. 1J is a circuit with an integral resonator and enhancer circuit.

FIG. 1K is a switching circuit for a voltage sensing resonator.

FIG. 1L is a schematic of an impedance transformation network.

FIG. 2A is a schematic of a system for characterizing the frequency response of the detector.

FIG. 2B is a sinusoidal waveform having different epochs in voltage versus time.

FIG. 2C is a plot of voltage versus time for a retrieved waveform averaged over five epochs.

FIG. 2D is a plot of amplitude versus voltage and measured amplitude versus time for a peak input voltage and peak voltage value of the reconstructed waveform.

FIG. 3A is a plurality of signals plotted relative to an MR and EEG signal.

FIG. 3B is an image reconstructed from the oscillation signal during an EPI sequence.

FIG. 3C is a plot of distance versus percentage for a sensitivity profile.

FIG. 3D is an image of when the power is reduced.

FIG. 3E is a sensitivity plot for the image in FIG. 3D.

FIG. 4A is a diagrammatic view of a rat relative to the detector of the present disclosure.

FIG. 4B is a plot illustrating the neuronal stimulation epochs and a rat with the detector thereon.

FIG. 4C is an activation map overlapped on an atlas.

FIG. 4D is a modulated signal pattern for a stimulation applied on a rat's left forepaw.

FIG. 5A is histology brain slice and fluorescence images with a fiber injection spot in the S1FP region.

FIG. 5B is a diagrammatic view of a rat with an electrode in the brain and optical fiber.

FIG. 5C is an EEG pattern derived from FIG. 5B.

FIG. 5D is a plot of latency versus laser power with various epochs.

FIG. 5E is a plot of peak amplitude versus laser power.

FIG. 5F is a plurality of epochs versus time.

FIG. 5G is a plot of BOLD in percentage versus time using a signal reconstruction algorithm.

FIG. 5H is a brain activation map, where regions with synchronized intensity modulation were highlighted.

FIG. 5I is a plot of averaged BOLD time courses for the activation region.

FIG. 5J is a plot of an averaged BOLD response for each epoch with different light intensity.

FIG. 5K is a plot of EEG peak intensity at two different laser powers.

FIG. 5L is a BOLD peak response under the two different laser power levels used in FIG. 5K.

FIGS. 6A-6E are reconstructed LFP traces as using optogenerated stimulation under different light powers.

FIGS. 7A-7E are reconstructed LFP traces obtained during optogenetic stimulation of a rat using different light widths.

FIGS. 8A-8D are reconstructed traces obtained during optogenetic stimulation of a rat under different light power.

FIG. 9 is a plot of LFF versus time illustrating no spikes from a photoelectric effect.

FIGS. 10A and 10B are reconstructed LFP traces during forepaw stimulation of a rat with different voltages versus time.

FIG. 11A is a plot of raw signal versus slice index before high pass filtering.

FIG. 11B is a plot of a clean signal versus line slice index show spike removal.

FIG. 11C is a plot of echo intensity versus line index for a positive gradient.

FIG. 11D is a plot of echo intensity versus line index for a negative gradient.

FIG. 11E is a transform formed into a single image frame.

FIG. 11F is a raw EEG signal containing repetitive base line variations that was synchronized with individual slice acquisition.

FIG. 11G is a plot of average base line pattern having 43 positive and negative peaks.

FIG. 11H is a plot of base line correction versus slice index.

FIG. 11I is a plot of a clean signal versus slice index.

FIG. 11J is a plot of an EEG signal versus time incorporating acquired delay.

FIG. 11K is an EEG plot versus time for a delay value interpolation.

Corresponding reference numerals indicate corresponding parts throughout the several views of the drawings.

### DETAILED DESCRIPTION

Example embodiments will now be described more fully with reference to the accompanying drawings.

A detector circuit or detector 10 is referred to as a Wireless Integrated Sensing Detector for simultaneous EEG and MRI (WISDEM detector) herein. The detector 10 retrieves low and high frequency signals, respectively. The feasibility and performance of WISDEM was tested to retrieve low-frequency voltage signals when a train of sinusoidal waves were directly injected into the sensing electrodes. Furthermore, the imaging performance of the detector is tested by observing robust EPI-BOLD in the S1 forepaw region (S1FP) when the rodent is given electrical forepaw stimulation. Lastly, optogenetic stimulation is combined with simultaneous acquisition of local field potential and fMRI signals in the S1FP region to expand the applicability of WISDEM. These results demonstrate the reliability of WISDEM for functional neuroimaging in rodents, boosting performance of the individual modalities via their complementary strengths to opening new avenues in brain research to interpret fMRI signals based on better understanding of the neurovascular coupling.

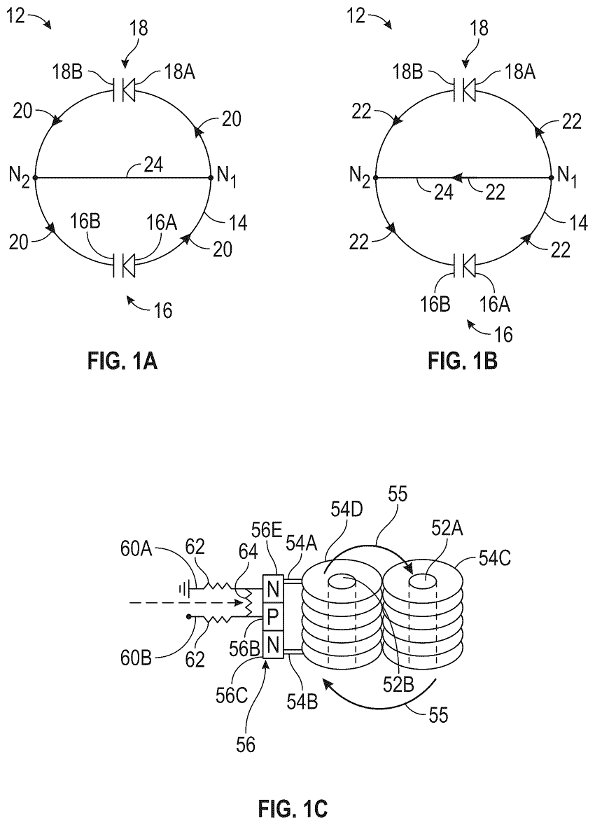

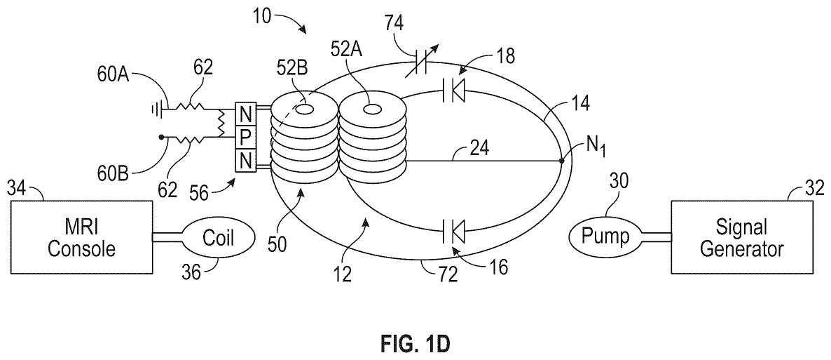

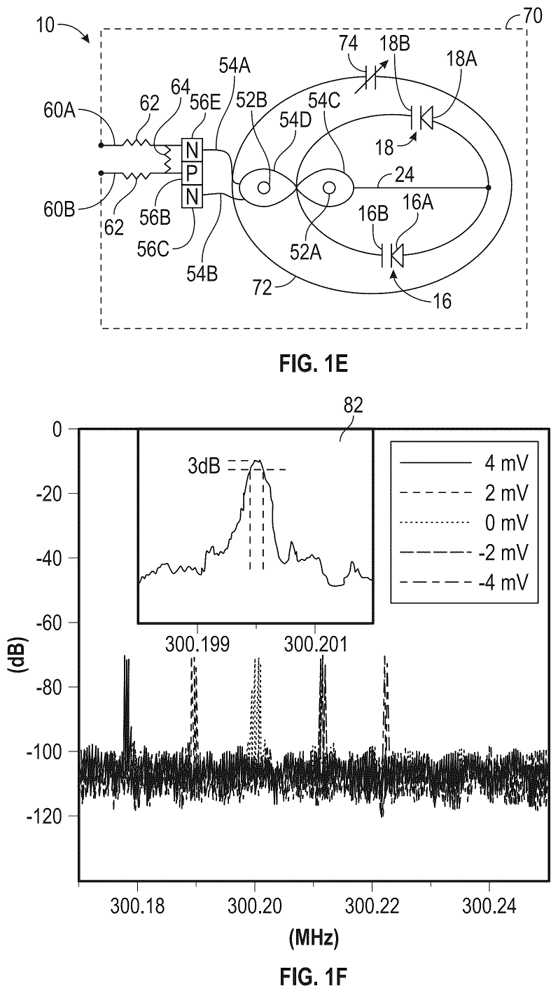

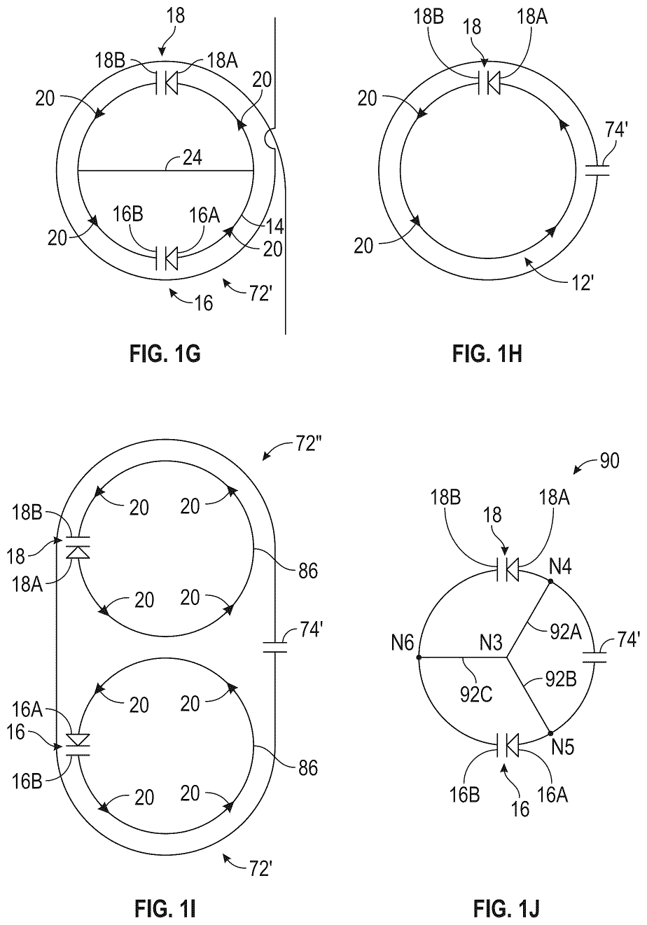

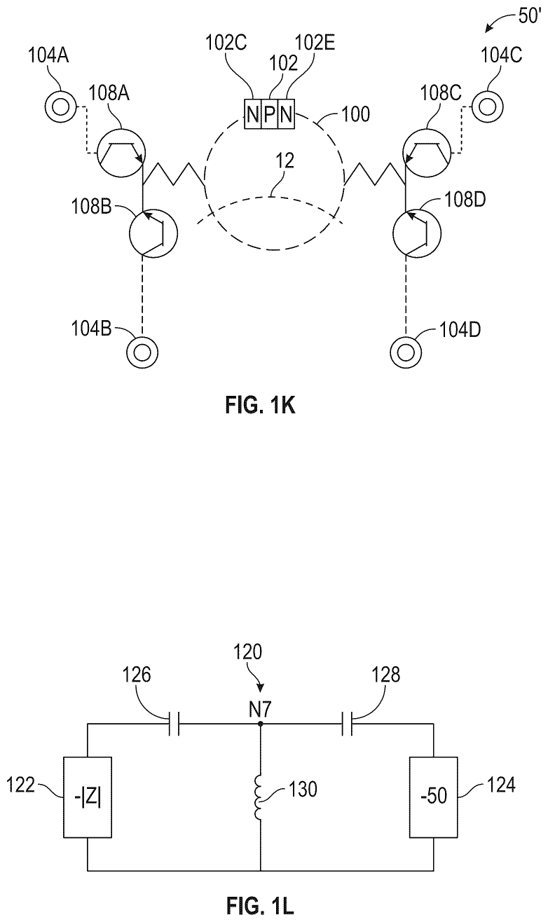

Referring now to FIGS. 1A-1E, various aspects of the detector 10 are set forth. The detector 10 includes a parametric resonator circuit or parametric resonator (PR) 12 as is shown individually in FIGS. 1A and 1B. The parametric resonator 12 has a loop 14 that has an axis that extends out of the page from the center of the loop 14. The loop 14 is formed of conductive material and is continuous has a circular shaped conductor pattern. Although the circular-shaped loop 14 is illustrated, other shapes such as ellipses and rectangles may be used. The loop 14 has a pair of varactor diodes 16, 18 (varactors) connected in a head-to-head configuration and creating a resonance mode with circular-shaped current flow illustrated by the arrows 20 in FIG. 1A. The varactor diodes 16, 18 have respective anodes 16A and 18A adjacent to each other in a sequential path. Cathodes 16B and 18B are adjacent to each other in a sequential path. Arrows 22 are in the opposite direction in FIG. 1B.

The parametric resonator 12 also has a continuous center conductor 24 creating a second resonance mode with butterfly-shaped current flow shown in FIG. 1B which in this example is a circular-shaped loop-gap resonator with a continuous center conductor to bridge its virtual grounds. A first end of the center conductor 24 has a first node N1 between the anodes 16A and 18A. A second node N2 is formed at the second end of the conductor 24 between the cathodes 16B, 18B. The resonator 12 has a butterfly resonance mode in FIG. 1A at a lower frequency ω_{br} and a circular resonance mode in FIG. 1B at a higher frequency ω_{cr}-When a pumping signal is applied from a pump 30 at a signal generator 32 at approximately the sum frequency of these two modes ω_{br}+ω_{cr}, the resonator 12 can oscillate at frequencies (ω_{b} and ω_{c}) that are close to the resonance frequencies (ω_{br} and ω_{cr}) of individual modes, i.e., ω_{b}˜ω_{br} and ω_{c}˜ω_{cr}. Once the pumping signal ωₚ is determined by an external frequency synthesizer or the signal generator 32, it will also determine the sum of butterfly and circular oscillation frequencies, i.e., ωₚ=ω_{b}+ω_{c}. If the butterfly mode oscillation signal falls within the detection band of an MRI scanner or console 34, the signal can be detected by a standard MRI coil 36. As explained in greater detail below, the oscillation frequency ω_{b} has a linear relation with the resonance frequency ω_{br}. If at the same time, the butterfly mode also interacts with an MRI signal that is separated from ω_{b} by an offset Δf that is smaller than the imaging bandwidth, the MRI signal will interact with the oscillation signal, creating a down-converted signal at Δf that can frequency-modulate the oscillation signal at the same time. In this way, both the low-frequency EEG signal and the high-frequency MRI signal can be encoded onto the same carrier wave for wireless transmission.

As is best shown in FIGS. 1C, 1D and 1E the WISDEM detector 10 has a voltage sensing resonator (VSR) circuit or resonator 50 for short. The resonator 50 has two parallel rods 52A, 52B consecutively wrapped by a continuous wire 54 having a first end 54A and a second end 54B. In this example, an enameled copper wire with five counterclockwise turns forms a coil 54C on the first rod 52A and another five clockwise turns forms a coil 54D on the second rod 52B. That is, the wire 54 is wrapped in a figure-eight pattern around the first rod 52A and a second rod 52B. Arrows 58 in FIG. 1C show the direction of the magnetic field between the first rod 52A and the second rod 52B.

The resonator 50 has a transistor 56. In this example, the transistor 56 is a bipolar junction transistor (BJT) having an NPN configuration. The transistor 56 has an emitter 56E, a base 56B and a collector 56C. The first end 54A of the wire 54 is electrically coupled, such as by soldering, to the emitter 56E. The second end 54B is electrically coupled to the collector 56C, such as by soldering. A pair of electrodes 60A and 60B for sensing and grounding were connected to the base 56B and emitter 56E, respectively, through 10-kQ resistors 62. The emitter 56E and base 56B were connected by a 475-kQ resistor to provide sufficient internal impedance.

The voltage sensing resonator (VSR) 50 was overlapping across the edge of the parametric resonator 12, with one coil 54C of the wire 54 and rod 52A sitting inside the conductor pattern of the parametric resonator 12 and the other coil 54D and rod 52B sitting outside the loop 14, thus creating effective coupling with the circular mode resonance of the parametric resonator 12. Because both coils 54C and 54D were symmetric with respect to the horizontal center conductor 24 of the parametric resonator 12, the voltage sensing resonator 50 was decoupled from the butterfly mode of the parametric resonator 12.

The parametric resonator 12 may be formed on a circuit board 70 which is planar. The rods 52A and 52B are normal to the plane of the circuit board 70. The center conductor 24 is also in the plane of the circuit board 70. From an axial view as shown in FIG. 1E the centers of the rods 52A and 52B are in alignment or collinear in the axial view and in the axial view are in alignment with the center conductor 24.

When the WISDEM detector 10 was activated by a pumping signal at approximately the sum frequency of the circular and butterfly resonance frequencies, the WISDEM detector 10 produced sustained oscillation signals for both resonance modes, which could be detected by a standard MRI coil that was cable-connected to the scanner console 34.

An enhancer circuit 72 in this example is oblong and surrounds at least the loop 14 of the parametric resonator 12. The enhancer circuit 72 is disposed on the plane of the circuit board 70. A trim capacitor 74 is disposed in the enhancer 72 so the enhancer circuit 72 may be tuned with respect to the resonance frequency.

When a bias voltage was applied across the pair of electrodes, 60A, 60B, the oscillation frequency was shifted at a rate of 5.5 kHz/mV (f). This frequency-to-voltage ratio (FVR) was 55-fold larger than the 3 dB-linewidth of the oscillation peak, (˜100 Hz as shown below, enabling sensitive detection of a bias voltage as small as 18 uV.

To fabricate a parametric resonator, a CNC milling machine was used to create a circuit pattern on a copper clad G10 circuit board 70. This pattern consisted of the circular conductor loop 14 with an inner diameter of 13.46 mm and an outer diameter of 14.46 mm, leading to an effective inductance of 29.9 nH. Within this circuit pattern, the upper and lower half circles had split gaps that were filled by varactor diodes 16, 18, such as BBY53 from Infineon, Germany, connected in head-to-head configuration as described above. As a result, the resonator had a resonance mode at 399.5 MHZ (Q=79) with circular-shaped current flow shown in FIG. 1A. By connecting the two virtual voltage grounds of the circular mode with a horizontal conductor, a second resonance mode was created at wor=300.2 MHZ (Q=77) with butterfly-shaped current flow shown in FIG. 1B. Because the horizontal conductor 24 was connecting the virtual voltage grounds of the circular mode, introduction of the second resonance mode will hardly affect the first resonance mode. To efficiently activate the parametric resonator at the sum frequency of its circular and butterfly modes, pumping field was locally concentrated by an oblong shaped enhancer surrounding the parametric resonator. Fabricated out of a loop conductor with a 15.46-mm width and a 20-mm length, the enhancer was empirically tuned by the trim capacitor 74 that filled its conductor gap. As a result, when the parametric resonator 12 was enclosed inside enhancer circuit 72, its circular mode resonance frequency was decreased to ω_{c}=381.0 MHZ (Q=79) while its butterfly mode resonance frequency remained unchanged at 300.2 MHz. Concurrently, the enhancer circuit resonance frequency was adjusted to 676 MHZ, which was slightly below the sum of butterfly-mode resonance frequency (ω_{br}=300.2 MHZ) and circular-mode resonance frequency (Wcr=380.8 MHZ).

The voltage sensing resonator 50 had a figure-8 conductor pattern. It was fabricated by wrapping a 32-G enameled copper wire 54 around two 1.46-mm diameter rods 52A, 52B that were separated by 1.8 mm. Each counterclockwise turn in the first rod 52A was followed by a clockwise turn in the second rod 52B. In this way, five turns with opposite orientations were wrapped around each rod before the two end terminals were connected to the emitter 56E and collector 56C of the bipolar junction transistor 56. On example of a transistor is an MT3S111 for Toshiba, Japan, creating an effective resonance at 386 MHz (Q=75). The base 56B was connected to the emitter 56E via a 475 kOhm resistor 64. The 475-kOhm resistor 64 can neutralize excessive charge accumulated on the base 56B while maintaining sufficient internal impedance for the transducer. By connecting the base 56B with a sensing electrode 60B via a 10-kOhm resistor 62 and the emitter 56E with a grounding electrode 60A via another 10-kOhm resistor 62, the resonance frequency Wor of the voltage sensing resonator 50 can be effectively modulated by the bias voltage applied across the electrode pair 60A, 60B. Meanwhile, the two 10 kOhm resistors 62 can effectively isolate the entire RF circuit from the sensing electrodes 60A, 60B that directly touch biological tissues, thus improving circuit stability. According to the voltage division relation, these two 10-kOhm resistors 62 will only reduce the sensing voltage by a factor of 4% when they are serially connected to the internal impedance of the transducer that is mostly defined by the 475-Ohm resistor between the base 56B and the emitter 56E.

When the voltage sensing resonator circuit 50 was overlapping across the circular edge of the parametric resonator with one coil 54C sitting inside the parametric resonator and another coil 54D sitting outside the parametric resonator 12 in the axial view, the resonator 50 could effectively couple with the circular mode of the parametric resonator 12 and decreased the circular mode resonance frequency to 374.8 MHZ (Q=67). That is at least a first portion of the voltage sensing resonator circuit is inside the loop and a portion is outside the loop. Both circles of the voltage sensing resonator 50 were symmetrically distributed across the center conductor line of the parametric resonator 12, the voltage sensing resonator 50 interaction with the butterfly mode of parametric resonator was effectively cancelled. As a result, the VSR 50 was effectively interacting with only the circular mode of the parametric resonator 12, enabling effective modulation of the oscillation frequency.

Referring now to FIG. 1F, when a pumping signal was provided at 675.0 MHz by a loop antenna, the parametric resonator 12 had sustained oscillation current at ω_{b}=300.2 MHz and ω_{c}-374.8 MHz. When the DC bias voltage across the pair of sensing electrodes was varied, the oscillation signal shifted at a rate of 5.5 kHz/mV. This rate of frequency shift was defined as the frequency-to-voltage ratio (FVR). The narrow linewidth ˜100 Hz as shown by the figure insert 82 in FIG. 1F of oscillation peak compared to large voltage-induce frequency shift will enable the wireless detector to identify input voltages as small as 18 uV.

Referring now to FIG. 1G, the enhancer circuit 72′ is changed with the same parametric resonator 12 of FIG. 1A. The enhancer circuit 72′ is made by wrapping a wire 84 around the parametric resonator 12 for one turn. The two ends of the enhancer can be connected by capacitors so that the enhancer can effectively couple to time-varying magnetic field and directly activate the parametric resonator. Here, the two ends of enhancer are left open and extended towards opposite directions like a dipole antenna, so that the enhancer can convert time-varying electric field into time-varying magnetic field.

Referring now to FIG. 1H, the double resonant parametric resonator 12 is with a single resonant parametric resonator 12′ by removing the varactor diode 16. The two oscillation signals therefore share one resonance mode. The self-disconnected enhancer loop 72 is replaced by a circular loop that is self-connected by a fixed capacitor 74′.

Referring now to FIG. 1I, the loop in FIG. 1A is split along the center horizontal conductor 24, to form two coupled loops 86,88 with the same diodes of FIG. 1A to provide two resonance frequencies. The enhancer circuit 72″ is elongated with the two coupled looped 86,88 enclosed therein. The two loop circuits 86, 88 provide two different resonant frequencies.

Referring now to FIG. 1J, the parametric resonator and the enhancer may be formed into an integrated parametric resonator and enhancer circuit 90. The enhancer's chip capacitor 74′ is connected symmetrically across the center at a common node N3. Node N3 is coupled to Node N4 between the varactor diode 18 and the capacitor 74′ with a first conductor 92A. Node N3 is coupled to Node N5 between the varactor diode 16 and the capacitor 74′ with a second conductor 92B. Node N3 is coupled to Node N6 between the varactor diode 18 and varactor diode 16 with a third conductor 92C.

In FIGS. 1H-1J, the capacitor 74′ may be a trim capacitor or a fixed capacitance capacitor, a static capacitor.

Referring now to FIG. 1K, an alternate resonator VSR 50′ is illustrated. In this example an inductor loop 100 connected to the emitter 102E and collector 102C of a bipolar junction transistor 102. To enable a single VSR to handle multiple encoding voltages, the VSR 50′ is coupled to multiple sensing electrodes 104A-104D via wireless switches 108A-108D. Each of the switches can be independently controlled by a phototransistor or photoresistor that is responsive to only one light color.

Referring now to FIG. 1L, an impedance transformation network 120 may be used to separate the sensing circuit and the oscillating circuit, so that current flow on the sensing circuit is suppressed, making wireless sensors easier to magnetically decouple from each other. The impedance transformation network 120 is used because the oscillating parametric resonators shown above may provide negative resistance across its varactor diodes 16,18. The negative resistance 122 may be converted into 50 Ohm impedance 124 via an impedance transformation network having a capacitor 126 coupled to the negative impedance 122 and a capacitor 128 coupled to the transformed impedance 124. An inductor 130 is coupled to a common node N7 between the capacitors 126, 128. By connecting this-50 Ohm output with an ordinary magnetic resonance probe, the quality factor of any probe irrespective of its internal circuit feature may be enhanced. The impedance transformation network makes it possible to create-50 Ohm impedance at any position along a long transmission line cable. This will enable boosting the effective quality factor of any ordinary Nuclear Magnetic Resonance probe. Enhancement of the quality factor enables performance of nonlinear NMR experiments, thus exploiting novel phenomena of dilute nuclear spins with strong coupling to the detector.

Retrieving low-frequency voltage signals applied on the sensing electrodes is described.

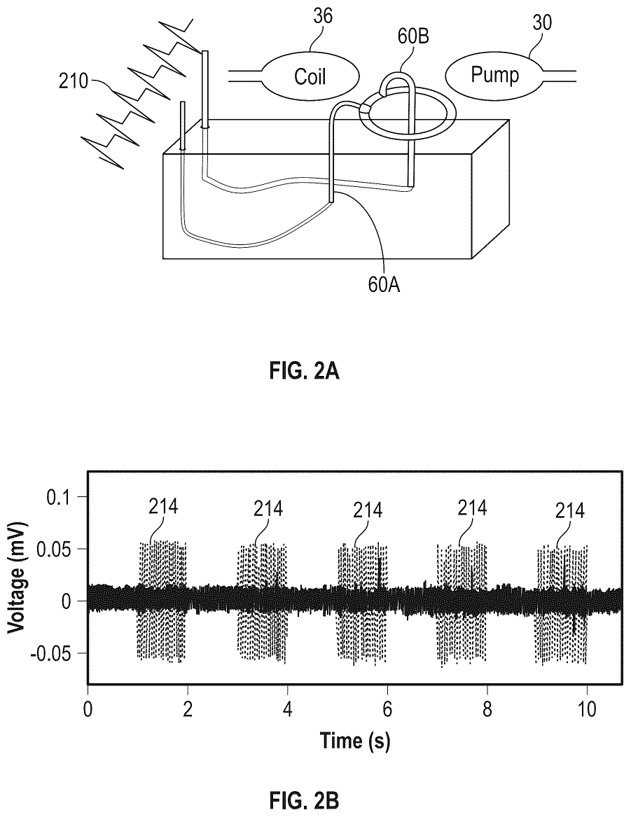

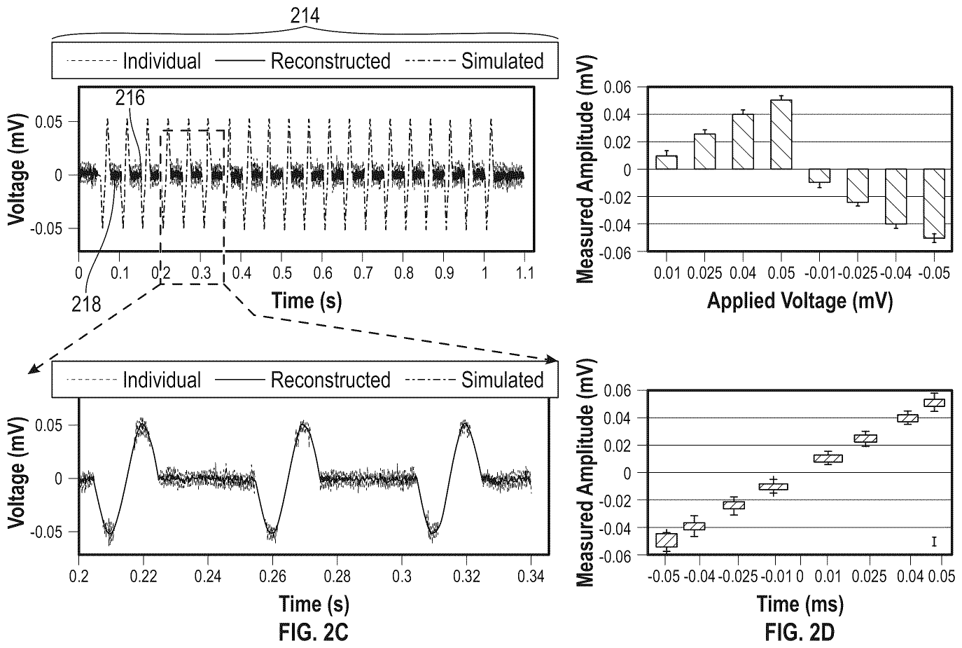

Referring now to FIGS. 2A-2D, a schematic representation of a configuration to characterize the frequency response of the WISDEM detector 10 when a train 210 of sinusoidal waves were directly injected into the sensing electrodes 60A, 60B. In FIG. 2B, the sinusoidal waveform was reconstructed by derivatizing the phase of oscillation signal and dividing this derivatized value with the frequency-to-voltage ratio, i.e. (dot/dt)/FVR. In FIG. 2C the zoom-in view of the first epoch containing 20 sinusoidal pulses. When the retrieved waveforms from multiple epochs were stacked together at 216, their averaged profile 218 was in good agreement with the simulated input waveform, as was clearly demonstrated in the zoom-in insert at the bottom left of the FIG. 2D. When the peak voltage of the input waveform was systematically varied, it had an obvious linear relation with the peak voltage of the reconstructed waveform.

To simulate neuronal input signals, waveforms produced by a function generator were injected into the sensing electrodes 60A, 60B. The function generator produced 20 pulses in an epoch 214 every other 1s. Each pulse had a duration of 20 ms, corresponding to one complete sinusoidal cycle. A 10 mm Bruker surface coil was placed behind the WISDEM to relay the oscillation signal into the scanner console. Once the oscillation signal was recorded, its instantaneous frequency shift was obtained by derivatizing the phase of oscillation signal followed by low pass filtering. Afterwards, the input waveform of FIG. 2B was obtained by dividing this frequency shift with the oscillator's frequency-to-voltage ratio (FVR=5.5 kHz/mV). FIG. 2C shows the retrieved waveform that was averaged over all the five epochs, which agreed well with the input waveform. When the input waveform intensity was varied in FIG. 2D, a 1:1 linear relation between the peak input voltage and the peak voltage value of the reconstructed waveform is shown. This high-level consistency demonstrates reliable voltage encoding capability of the WISDEM detector 10.

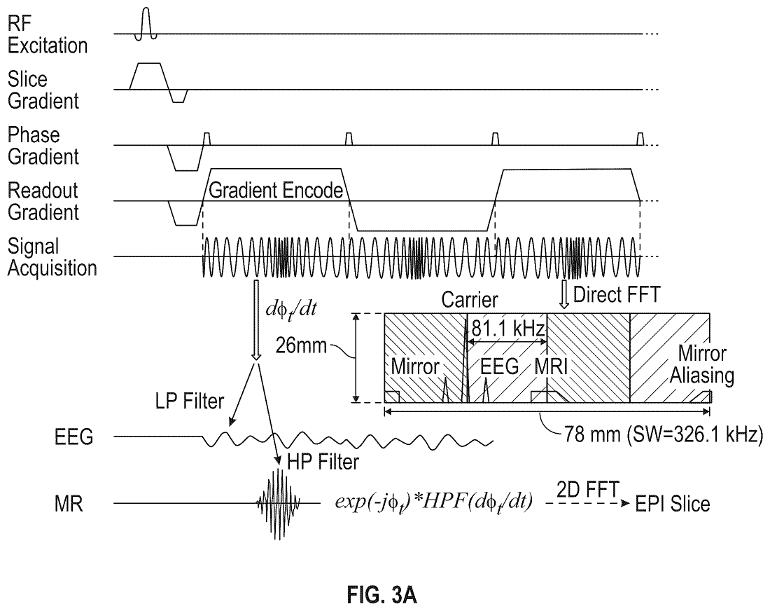

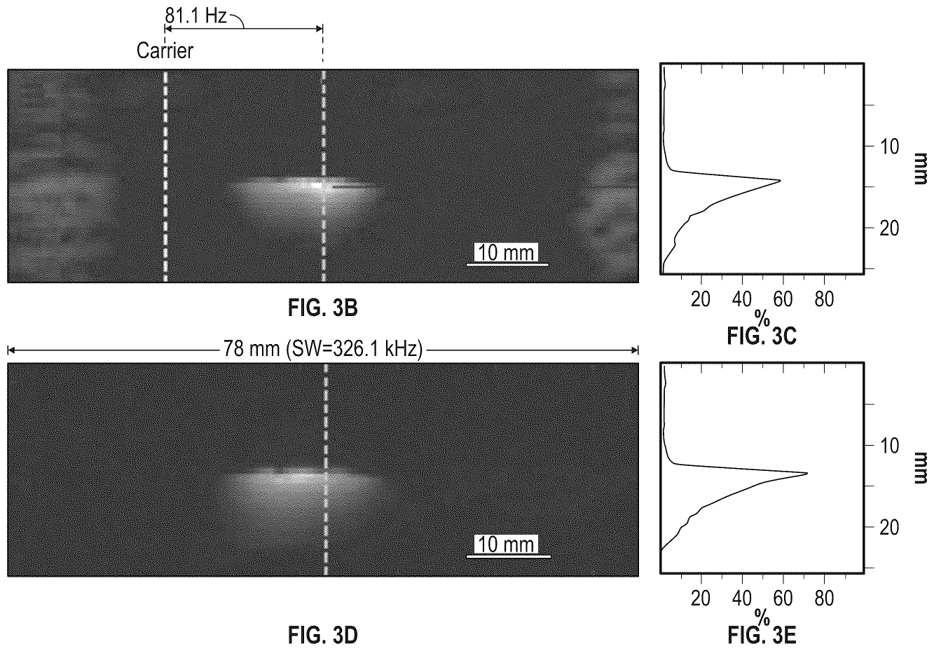

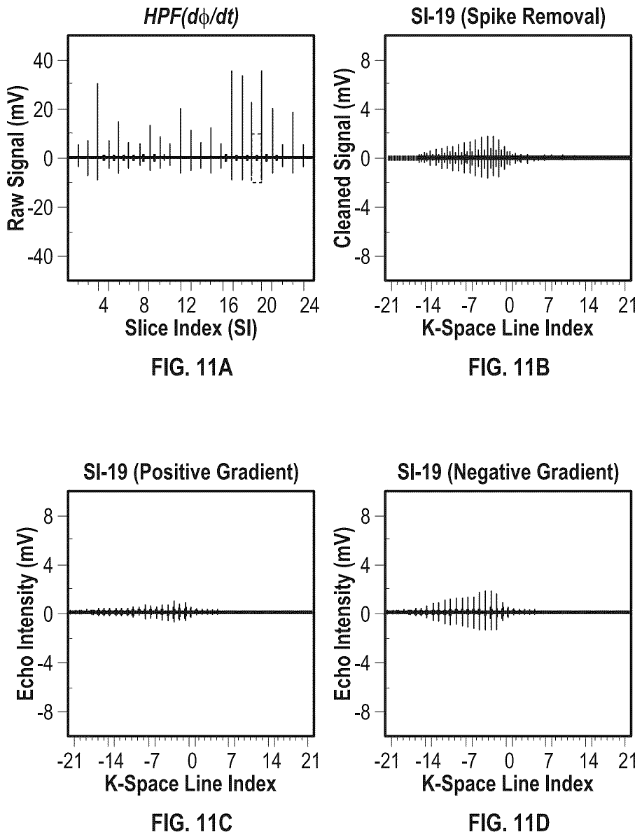

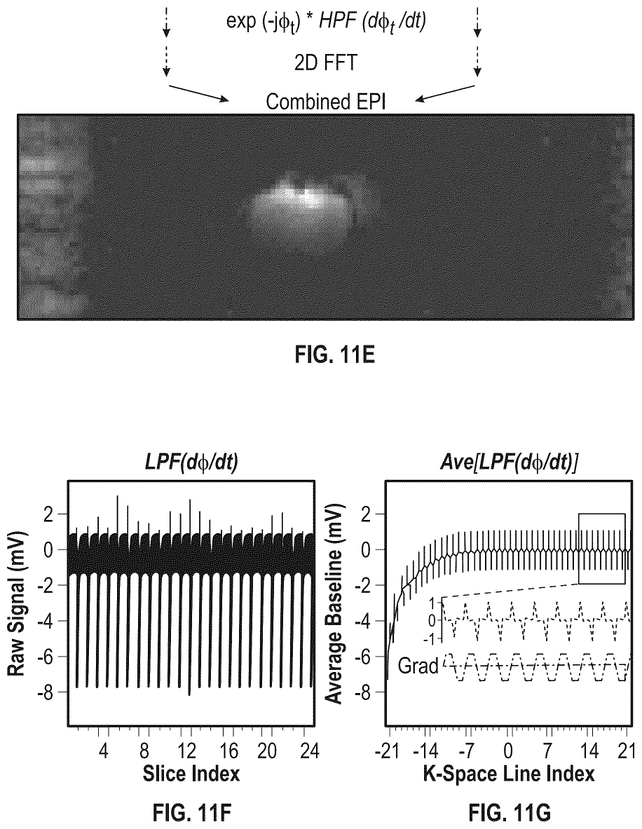

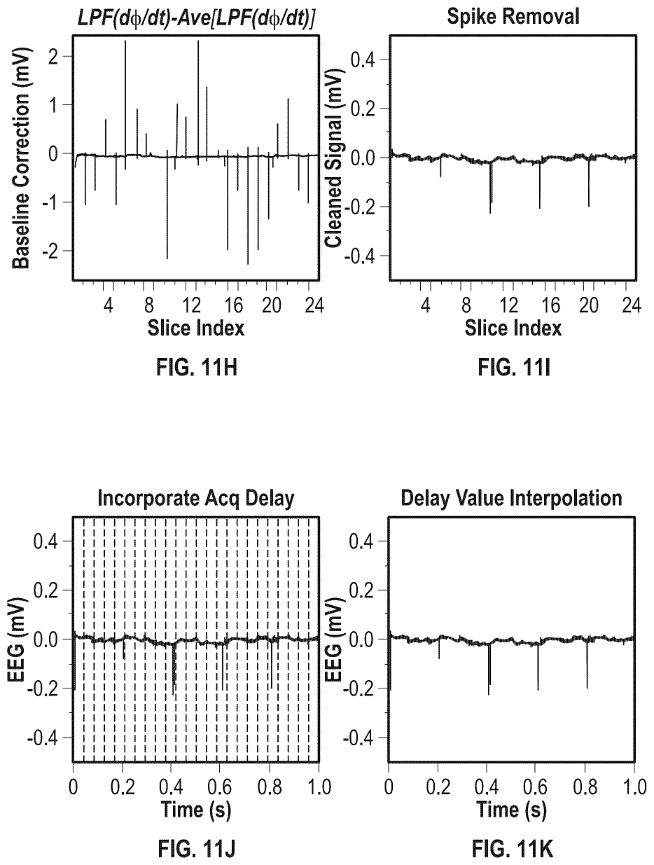

Referring now to FIGS. 3A-3B, retrieving high-frequency MR Signals may be performed. To evaluate the performance of the detector 10 for MR signal encoding using the Echo Planar Imaging sequence, the detector 10 was placed on an agarose phantom (1% agarose dissolved in distilled water). The pumping power was adjusted to 0.4 dBm above the oscillation threshold and continuously acquired the oscillation signal during the entire EPI acquisition period. The horizontal FOVₓ was enlarged to 3-fold the vertical FOV_{y} so that the spectral window was large enough to include the information-encoding sidebands. By empirically adjusting the pumping frequency, the oscillation signal was adjusted to ˜81.5 kHz above water resonance and aligned to the left quarter location in the frequency domain, thus separating from the image center by ¼ of a horizontal FOVₓ shown in FIG. 3A. In this way, the MR signal had the largest distance separation from its mirror and the aliased mirror. Compared to neuronal voltages that modulated the oscillation signal at <1 kHz speed, MRI signals modulated the oscillation signal at the offset frequency (e.g., ˜81.5 kHz), showing up as distinct sidebands in the frequency domain. According to the image reconstruction algorithm described in FIG. 3A and described in FIGS. 11A-K the phase Øt of the oscillation signal at each time point was derivatized and assigned the high-pass filtered value of this derivative dØₜ/dt as the amplitude signal Aₜ for that particular time point, i.e., Aₜ=HPF(dØₜ/dt). By multiplying this amplitude signal Aₜ with the phase term exp(−jØₜ) of the oscillation signal, a phase-sensitive signal exp(−jØₜ)*HPF(dØₜ/dt) was obtained for that time point. After applying 2D Fourier transformation on phase-sensitive signal series, the image slice was retrieved as shown in FIG. 3B. Because the mirrored signal and aliased mirror had opposite phase relations with respect to the MR signal, a dispersed pattern after 2D Fourier transformation and were not utilized in subsequent analysis.

The data processing part in FIG. 3B has special processing features. The horizontal field of view was made to be 78 mm in FIG. 3B, which is 3-fold the vertical field of view. As a result, a sufficient number of sideband images (left and right sides) that carry useful information can be incorporated. In order to correctly reconstruct 2D images, the phase of the oscillation signal as the phase of FM-demodulate signal is used.

More specifically in FIG. 3A during the gradient encoding periods of Echo Planar Imaging sequence, low-frequency EEG signals and high-frequency MRI signals were simultaneously encoded onto the same oscillation carrier wave that could be directly detected by a standard MRI coil. The oscillation carrier frequency was adjusted to overlap with the left quarter location (represented by the white dash line) of the field-of-view in the frequency domain, so that the MR signal was separated from its mirror and the aliasing of the mirror by largest distances. To retrieve time-domain signals, the oscillation carrier wave was first demodulated by derivatizing its phase angle, before being low-pass filtered to obtain EEG and high-pass filtered to obtain MRI. An example of this signal retrieval scheme was shown in FIGS. 11A-K. In FIG. 3B, a phantom image reconstructed from the oscillation signal recorded during the EPI sequence, using TE=20.381 ms, TR=997.648 ms, FOV=78×26×14.4 mm³, Matrix Size=129×43, Voxel Size=0.6×0.6 mm², Slice Number=24, Flip Angle=90°, Bandwidth=326087 Hz. The dispersed patterns near the left and right edges of the FOV came from the signal mirror and the mirror's aliasing that had opposite phase relations with respect to the original MR signal in the center.

As a result, they were not reconstructed correctly with the correct phase and were discarded for subsequent analysis.

As shown in FIG. 3D compared to a cable connected coil with identical dimension, the WISDEM detector 10 maintained ˜60% sensitivity in its sensitivity profile (along the yellow dashed line crossing through the image center). In FIG. 3D, when the pumping power was reduced beneath the circuit's oscillation threshold, the WISDEM detector 10 could only amplify and relay MRI signals, maintaining ˜75% sensitivity of a cable-connected coil.

To evaluate image sensitivity, the same procedure was repeated to obtain a second image (S2) and calculated the signal-to-noise ratio (SNR) of individual pixels by dividing the average intensity of individual pixels with the standard deviation of background signal intensity in the difference image.

$$SNR = \frac{( \vert {S}_{1} \vert + \vert {S}_{2} \vert ) / 2}{std ( \vert {S}_{1} \vert + \vert {S}_{2} \vert )}$$

For comparison purposes, the same EPI image was also acquired with a surface coil of the same dimension but with direct wired connection to the scanner console. Compared to this reference image, the image reconstructed from the oscillator maintained ˜60% the sensitivity of a directly connected coil shown in FIG. 3C. Besides full-scope operation as a wireless oscillator, the WISDEM could also operate as a wireless amplifier when the pumping power was reduced to ˜1 dBm below the oscillation threshold. As shown in FIG. 3D, when only performing its partial function for signal amplification and wireless transmission, the detector could retain ˜75% the sensitivity of a directly connected coil. Therefore, partial operation as a wireless amplifier would be more suitable for consecutive acquisition of MRI signals during the acquisition intervals of EEG signals, if simultaneous encoding of EEG signals is not required.

Retrieval of BOLD signals in vivo with electrical forepaw stimulation is described.

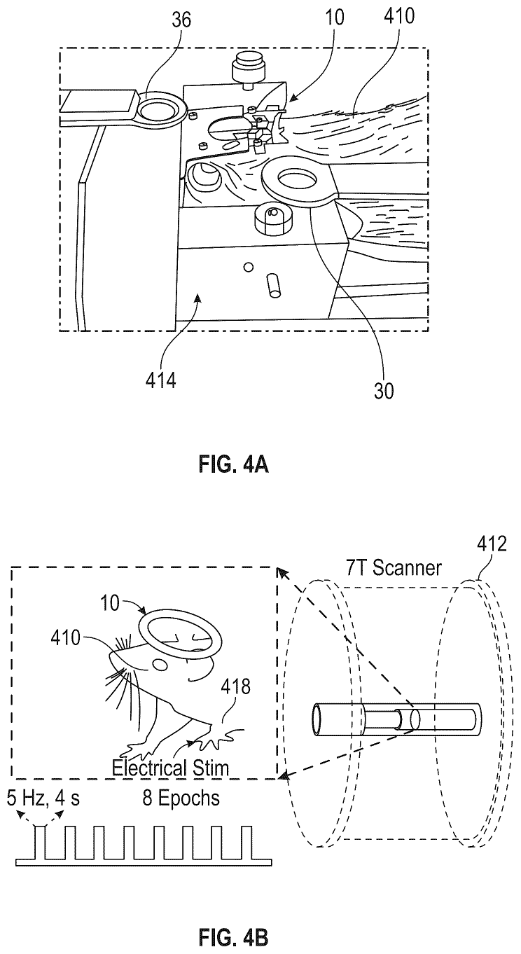

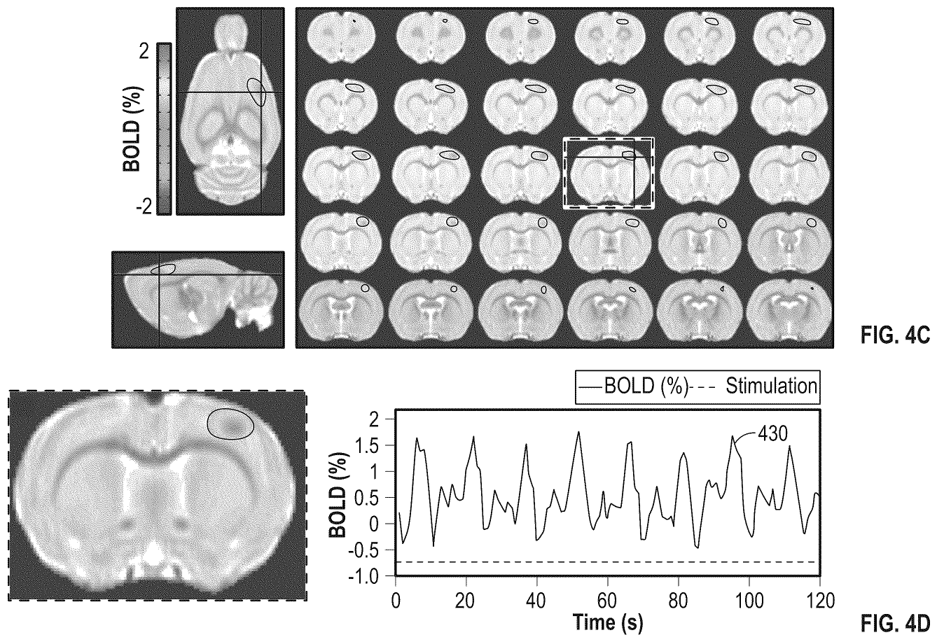

Next, the capability of the detector 10 for recording BOLD signals in vivo was determined. To verify the rat brain had hemodynamic responses to sensory stimulation, the rat 410 was placed inside an MRI scanner 412 and stimulated its somatosensory cortex via its forepaw in FIGS. 4A and 4B, using 0.33-ms biphasic electric pulses with 2-mA amplitude at 5-Hz repetition rate that last for 4s, followed by a 11s blanking period to restore the activated brain region to its resting state baseline shown in FIG. 4B. Concurrently during forepaw stimulation, the WISDEM detector 0 was activated by a pumping signal at 1 dBm beneath the detector's oscillation threshold so that Echo Planar Images could be repetitively acquired with enhanced amplitude and good sensitivity. After the amplified images were aligned with the standard SIGMA brain atlas, the correlation coefficient between the time-dependent signal intensity of each pixel and the ideal stimulation function was calculated, thus identifying brain regions that were activated by forepaw stimulation. As shown in FIG. 4C overlapped on the atlas, the S1FP region had a BOLD modulation pattern with the same periodicity (15 s) as the stimulation epoch, which is highly consistent with previous results using conventional surface coils. Within each epoch, the MR signal intensity had up to 1.5% modulation during the 4-s stimulation period before returning to the baseline level.

More specifically in FIG. 4A, EPI-based functional MRI using the WISDEM 10 from rats 410 upon electrical forepaw stimulation. The WISDEM detector 10 is disposed on top of a rat head that was fixed inside a cradle 414. The schematic diagram showed the rat secured inside the MRI scanner 412, with its left forepaw 418 stimulated by 8 epochs of electric pulses. Each epoch contained 333-μs biphasic pulses at 5 Hz repetition rate and 4-s duration followed by 11-s resting period. In FIG. 4C, when the WISDEM detector 10 was operating as an MR signal amplifier, the evoked BOLD fMRI maps showed a clear activation region in the forelimb area of the primary somatosensory cortex (S1FP) based on the SIGMA rat brain atlas, following tactile stimulation of the left forepaw 418 (n=5 animals, P_{(corrected)}<0.001). In FIG. 4D, the modulated signal pattern in the S1FP region was highly synchronized with the stimulation pattern 430.

Simultaneous Retrieval of BOLD and LFP signals in vivo with optogenetic stimulation is set forth.

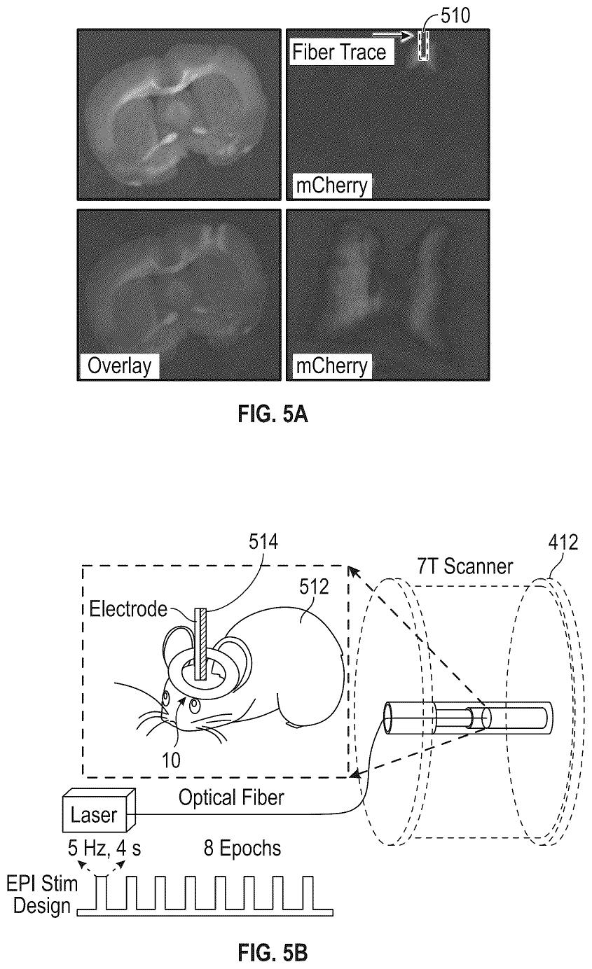

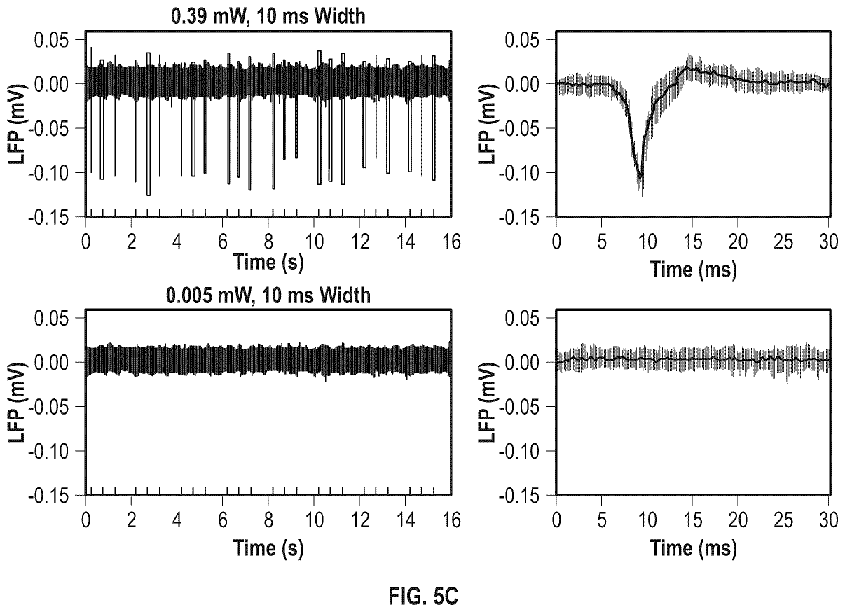

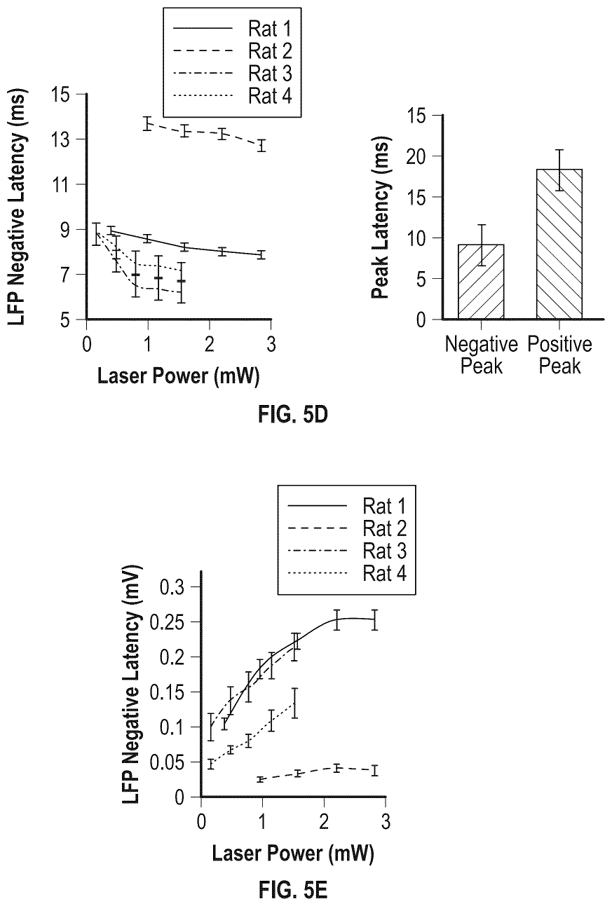

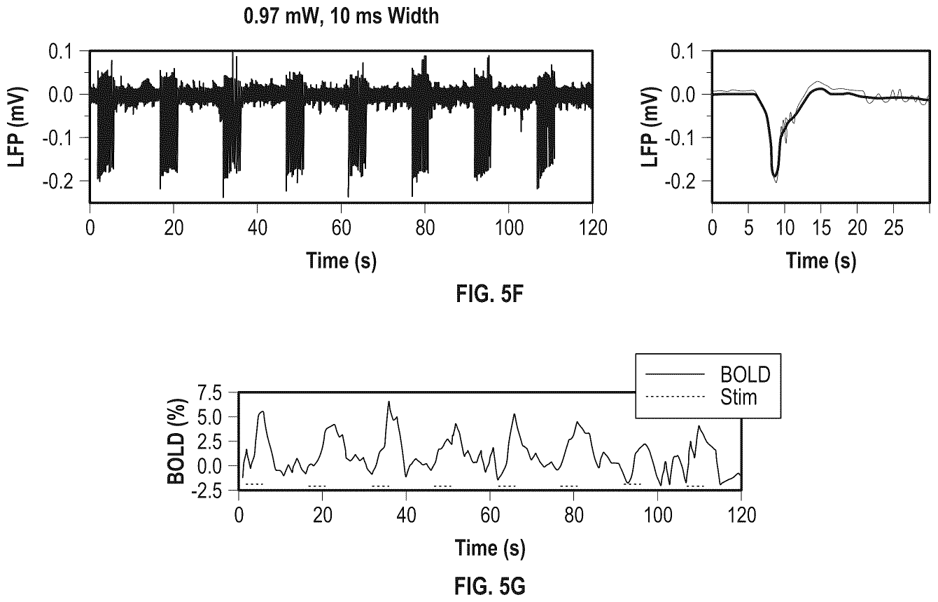

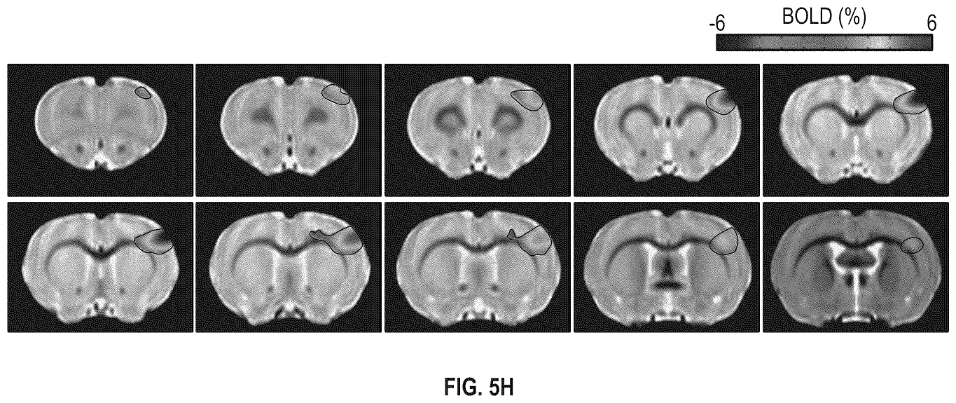

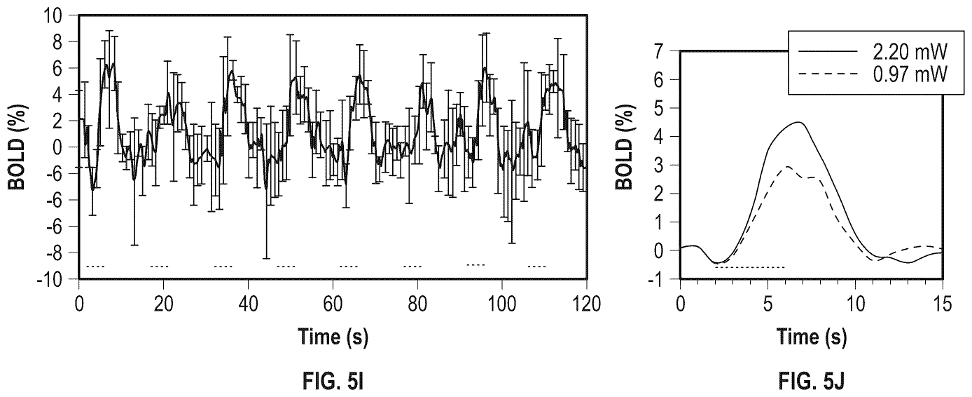

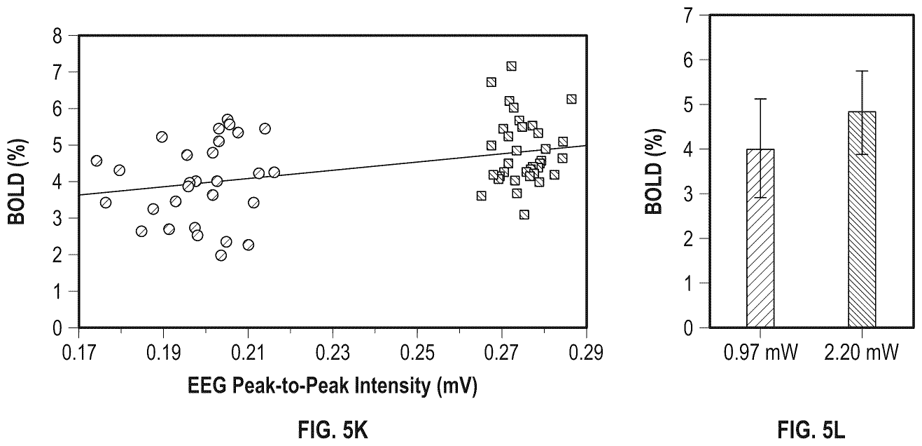

Referring now to FIGS. 5A-5L, WISDEM detector 10 for optogenetic-fMRI in rats is set forth. In FIG. 5A, the histology brain slice and fluorescence images showed the fiber injection spot 510 in the S1FP region with AAV-ChR2 expression. In FIG. 5B, the schematic diagram shows the rat 512 lying inside the MRI scanner 412, whose S1FP region was stimulated by an optical fiber 514 and recorded by the sensing electrode 60B. In FIG. 5C, in the absence of encoding gradients, the EEG pattern could be directly retrieved when the stimulation light power was as low as 0.39 mW. In FIG. 5D, when the laser power gradually increased, AAV-labelled neurons had stronger responses, leading to decreased latency time and in FIG. 5E increased peak amplitude. In FIG. 5F, in the presence of encoding gradients, the EPI sequence was implemented concurrently during optogenetic stimulation. The EEG signal was retrieved by low pass filtering the derivatized phase angle of the detector's oscillation signal, LPF (dØr/dt). To retrieve multi-slice MR images in FIG. 5G, a signal reconstruction algorithm described in FIG. 3A and FIG. 11 was implemented. The S1FP region showed a modulated signal pattern that was highly synchronized with the stimulation epoch and the EEG pattern. In FIG. 5H, the color-coded activation map depicted regions with synchronized intensity modulation that were overlapped on the SIGMA rat brain atlas (GLM-based t-statistics in AFNI was used. P (corrected)<0.001) of Block design). In FIG. 5I, averaged BOLD fMRI time courses from the activation region in S1FP upon optogenetic stimulation (n=4 animals, mean±SD). In FIG. 5J, averaged BOLD response for each epoch with different light intensities is obtained. In FIG. 5K, the EEG peak intensity and fMRI signal response show positive correlation for individual epochs. The differently shaded dots correspond to laser power at 0.97 mW (left side) and 2.2 mW on the right side. In FIG. 5L, the BOLD peak responses under two different laser power levels.

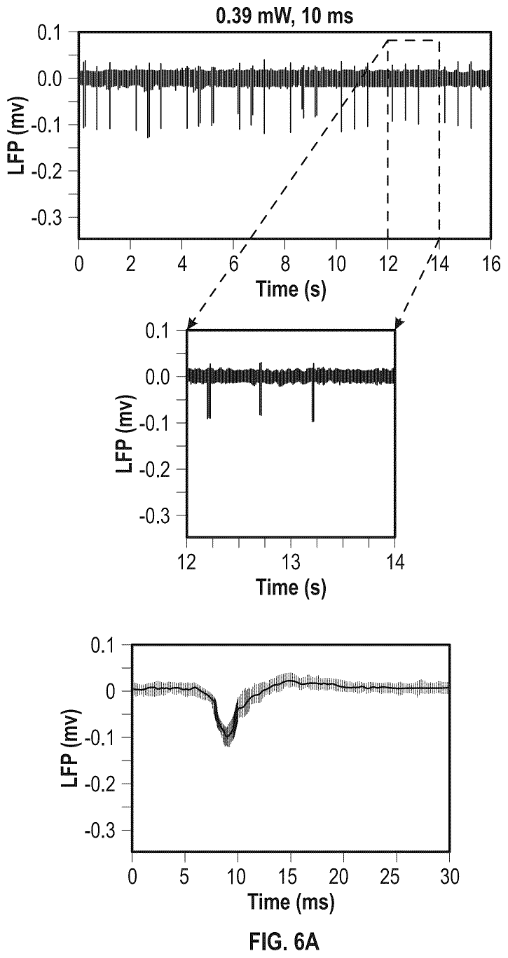

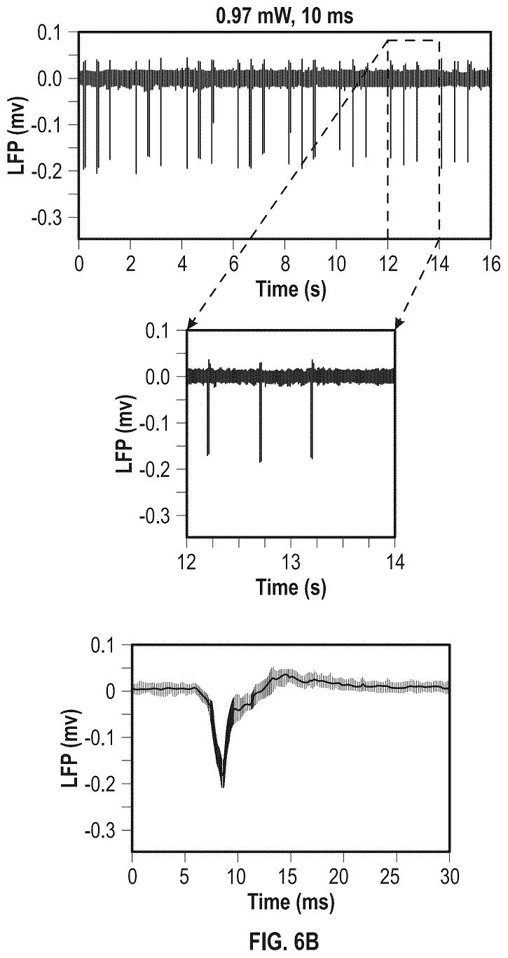

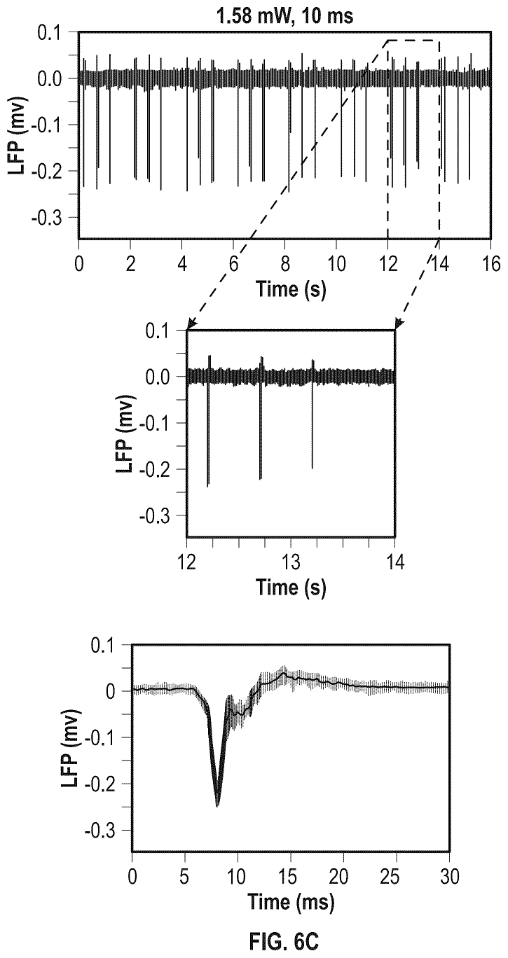

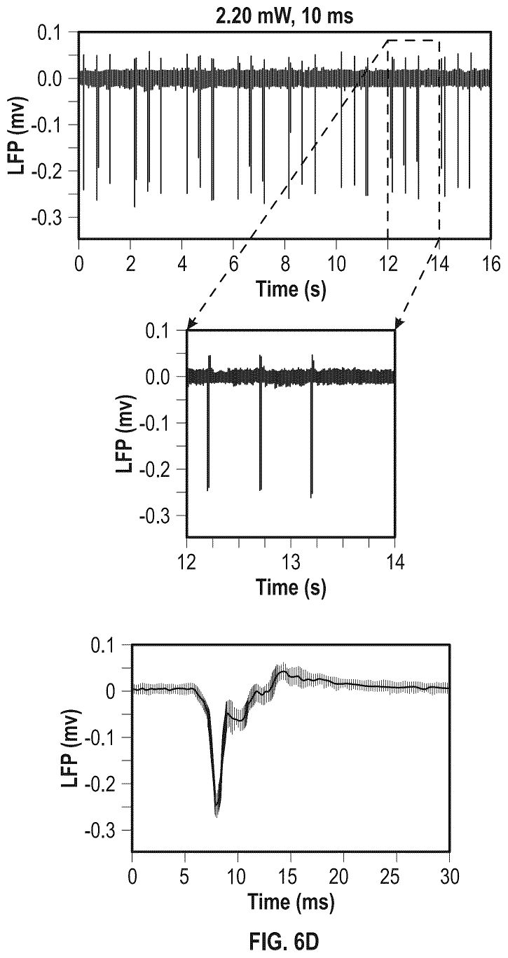

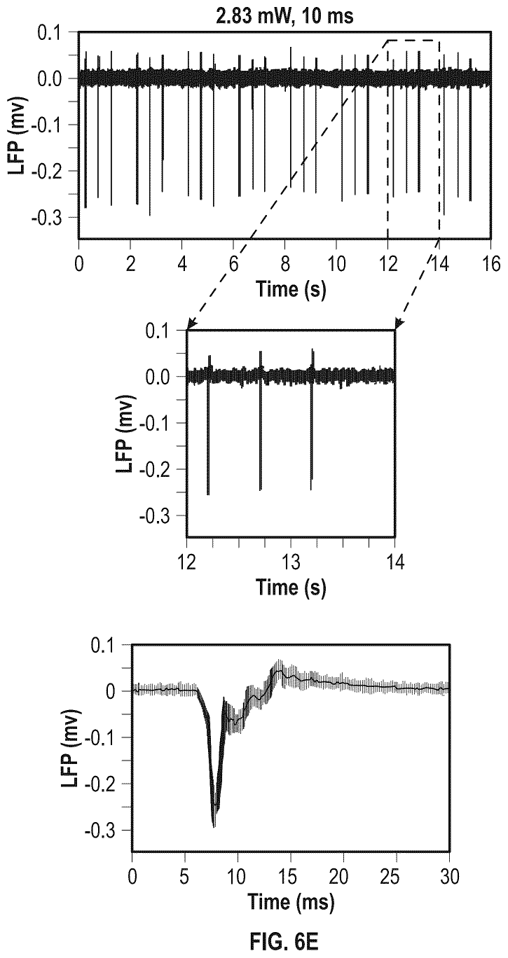

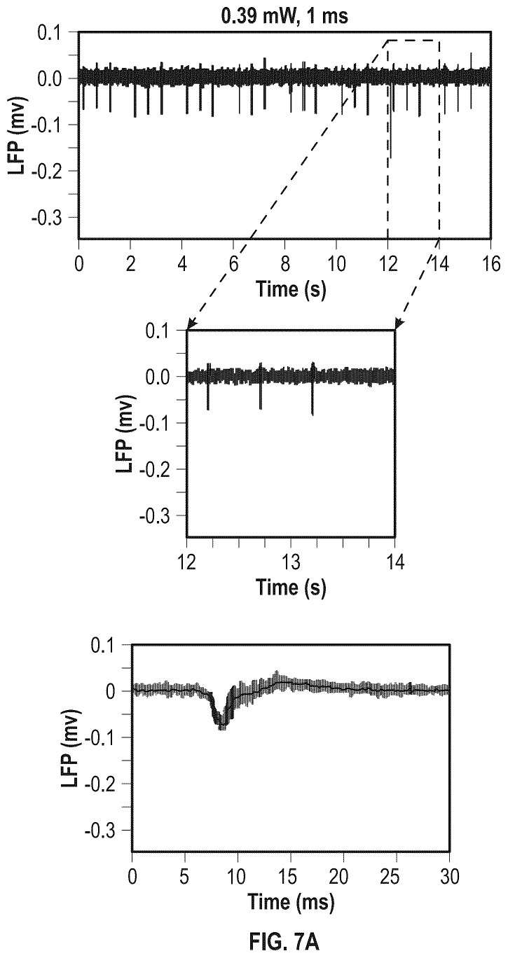

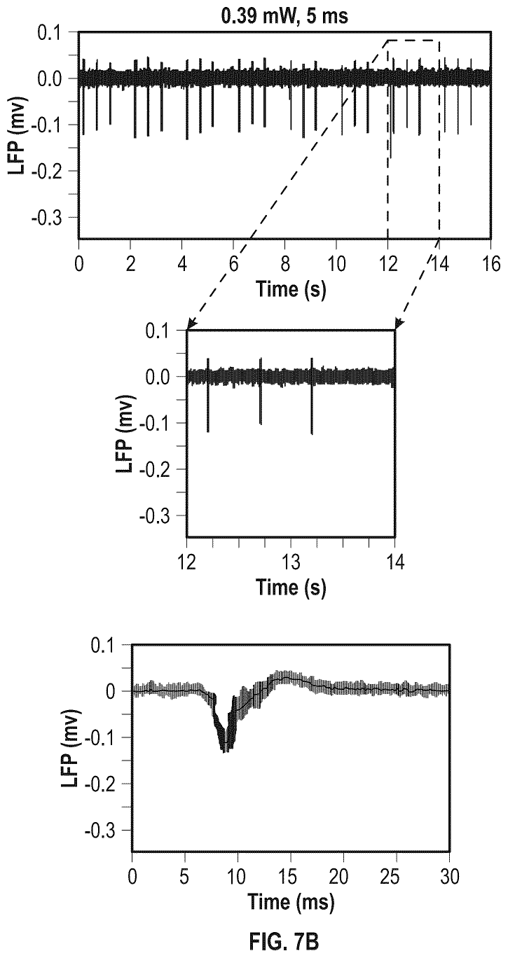

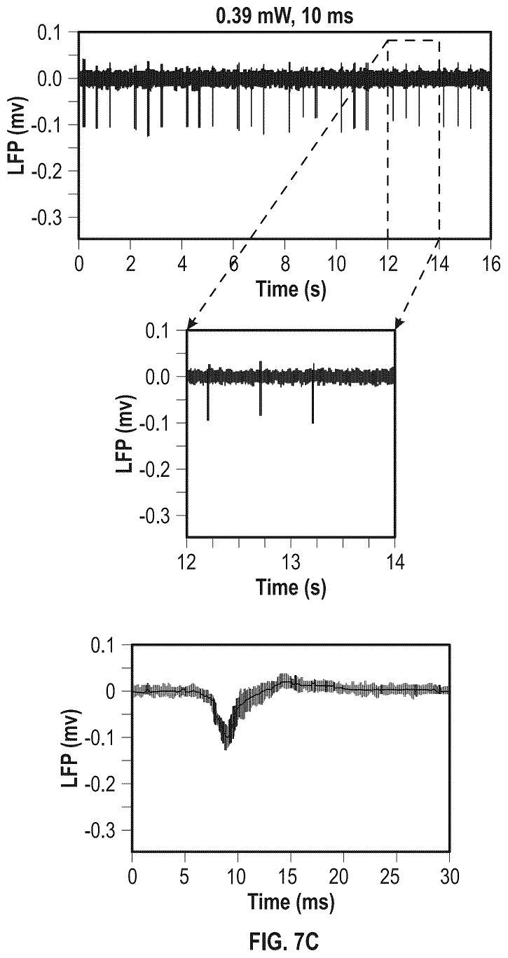

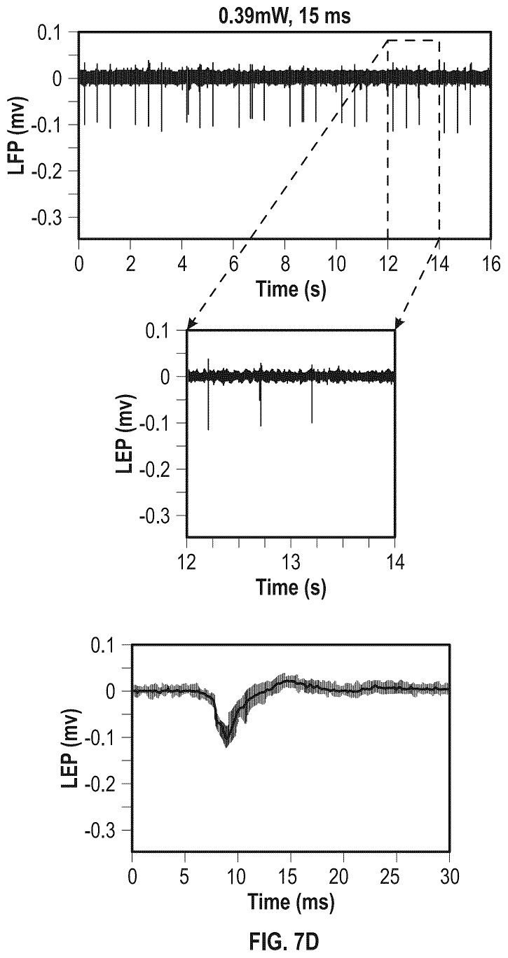

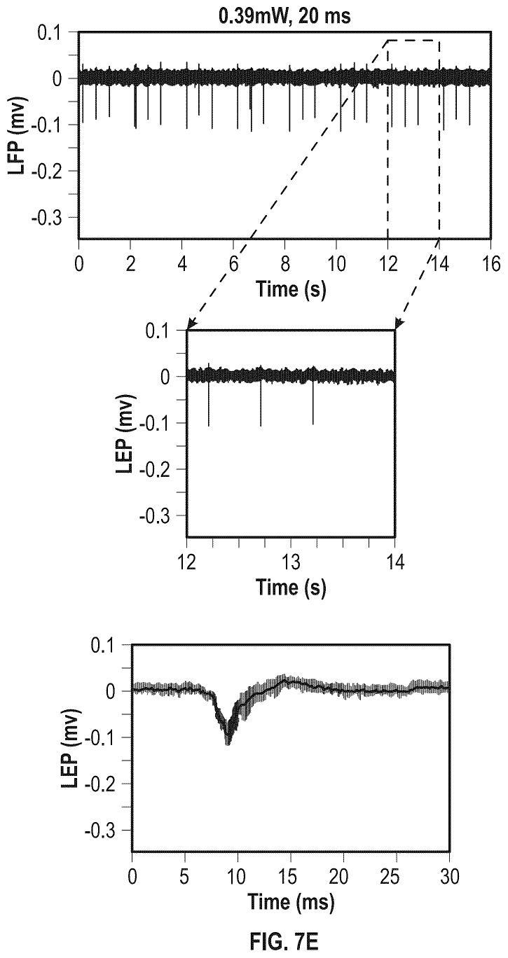

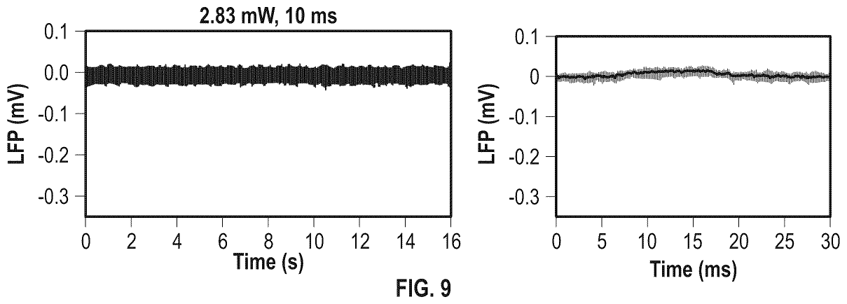

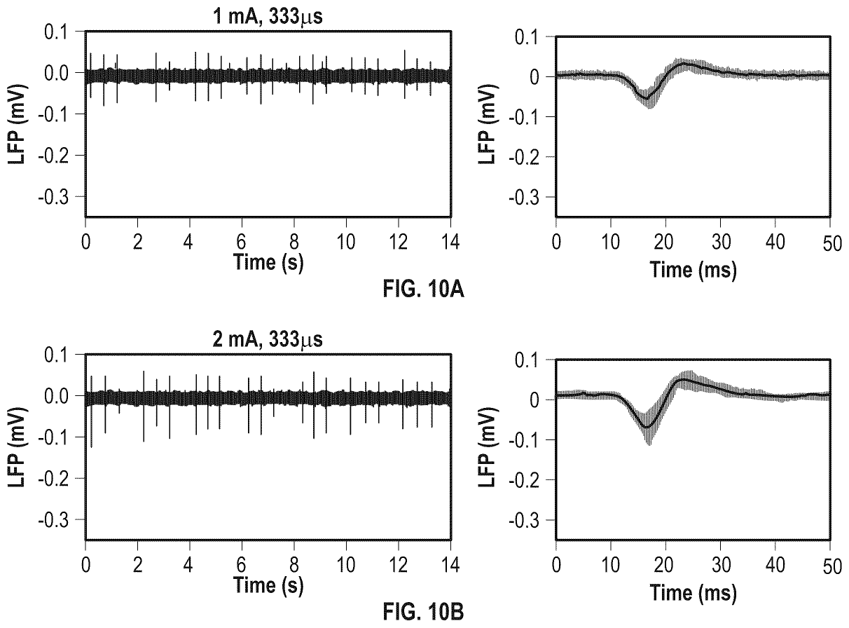

More specifically, to demonstrate the full-scope capability of the WISDEM, LFP during MR signal acquisition were recorded. Rats were stimulated by light pulses at 470 nm wavelength, with an optical fiber and an electrode inserted into the S1FP region that had been transfected with AAV5-CaMKII.hChR2 in FIGS. 5A and 5B. To confirm the sensing electrode was recording LFP signals, the detector's oscillation signals were acquired in the absence of encoding gradients or RF pulses when light stimulation was repetitively applied at 2 Hz for 1.5 s (3 pulses) followed by a 1 s rest interval. Then, the phase angle of the oscillation signal dØₜ/dt was derivatized to obtain time-dependent electrophysiological signals. As shown in the upper row of FIG. 5C, EEG spikes were clearly observable for low-power light at 0.39 mW. In a control experiment, the light power was reduced to 0.005 mW and observed disappeared LFP patterns as shown in the bottom row of FIG. 5C, thus attributing the negative peaks in the upper figure to light induced activity. EEG spikes were robustly recorded with laser power dependency (0.39, 0.97, 1.58, 2.20, 2.83 mW in FIGS. 6A-E) and laser width dependency (1, 5, 10, 15, 20 ms in FIGS. 7A-D). When the laser power is increased, decreased latency time for the negative peak was decreased as shown in FIG. 5D. When optical stimulation power was increased, the decreased latency time was also observed for the positive peak that always followed the negative peak in the EEG curve. No LFP spikes were observed when the same amount of maximum laser power was applied on a control rat without AAV-ChR2-mCherry expression (FIGS. 9A, 9B), thus once again attributing the negative peaks in FIGS. 6A-E and 7A-D to optogenetically evoked activities. Meanwhile, the increased stimulation power also led to larger peak intensity (FIG. 5E, n=4 animals). It is noteworthy that the orange curve for “rat 2” had larger deviation from the curves corresponding to the other three rats. This is because the electrode was inserted shallower than the virus injection point to verify the spatial specificity of optogenetic stimulation and the longer duration for neuronal currents to travel over a larger distance separation. To confirm the WIDSEM's full-scope capability, the same method was used to retrieve EEG signals when the rat was stimulated by electrical currents on its forepaw (FIGS. 10A-B). However, due to the relatively small neuronal responses within the recommend threshold of 2 mA as well as the larger signal dispersion, forepaw stimulation was not the first-line choice to evaluate neurovascular coupling activities.

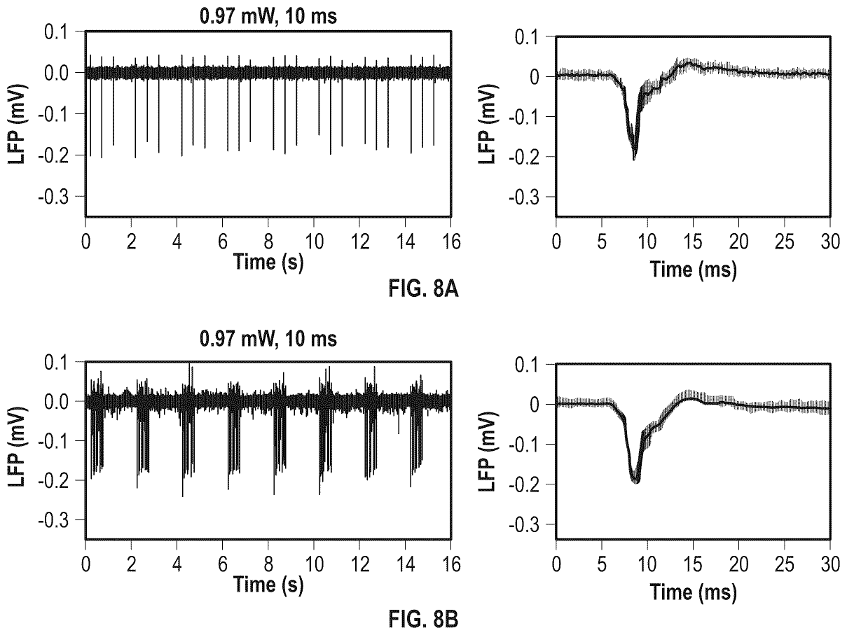

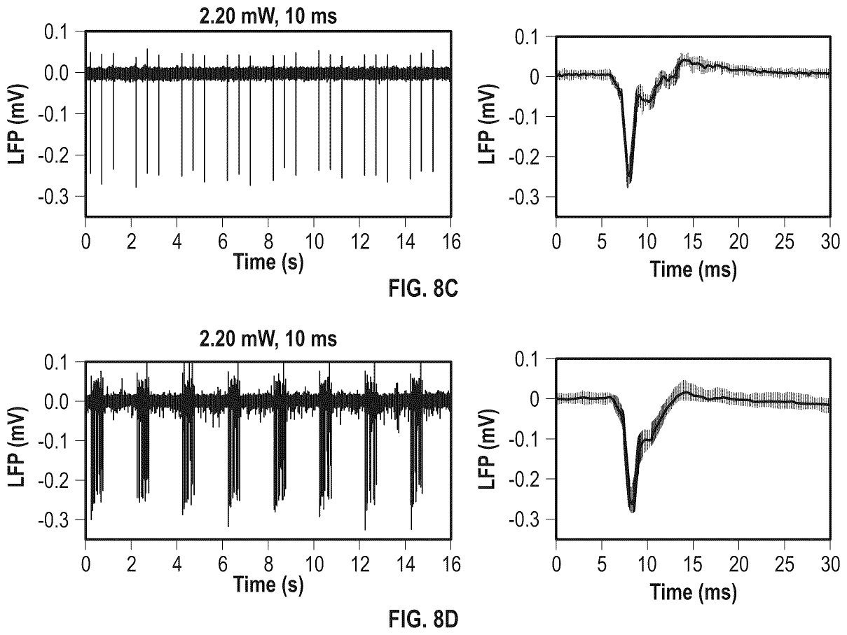

Simultaneously, Echo Planar Imaging sequence was repetitively performed (in the presence of encoding gradients and RF pulses) and concurrently recorded the oscillation signal during optogenetic stimulation. Using the reconstruction algorithm described in FIGS. 3A and FIGS. 11A-K, EEG and fMRI signals were simultaneously retrieved. When the optical stimulation power was 0.97-mW, the LFP pattern in FIG. 5F) had most peaks retaining similar amplitudes as those acquired in the absence of gradients or RF pulses in FIG. 6B. As shown in FIGS. 8A-8D, when the optical power level was increased from 0.97 mW to 2.20 mW, the LFP peaks retrieved in the presence and in the absence of RF pulses & encoding gradients maintained to have comparable intensity, thus demonstrating the robustness of the wireless oscillator for LFP signal encoding during MR signal acquisition. In the concomitantly acquired EPI image, the S1FP region had a periodically modulated pattern with an average of ˜3% intensity increase during the 4-s stimulation period of 0.97 mW pulses in FIG. 5G, which was highly consistent with previous studies using conventional surface coils. The fMRI signal pattern was also synchronized with the LFP pattern (FIG. 5F). Based on the mask defined in the color-coded activation map (FIG. 5H), the signal intensity was evaluated over multiple EPI experiments and consistently obtained a similar time-dependent fMRI modulation pattern in FIG. 5I. By plotting the fMRI signal change during each stimulation epoch with respect to the corresponding peak LFP intensity, an approximate linear relation between fMRI intensity change and LFP intensity in FIG. 5J was obtained, thus demonstrating the presence of neurovascular coupling effect that led to MRI signal modulation.

Optogenetic/fMRI is widely used to bridge the gap between cell-specific neuromodulation and animal behaviors, providing information across the entire brain. However, the mechanisms underlying the inhibitory/excitatory neuro-vascular coupling are still poorly understood. The proposed WISDEM platform combines, for the first time, LFP and BOLD measurements upon optogenetic stimulation without the need for extra recording equipment. The WIDEM detector can wirelessly communicate with any type of signal interface that is already available on commercial MRI scanners, thus providing an easy-to-access-tool to interrogate neuro-vascular coupling mechanisms in healthy and diseased brains. This setup further facilitates the combination of photometry for fluorescent calcium recordings with LFP and fMRI during optogenetic stimulation, thus creating a multi-modal fMRI platform to study brain functions across multiple scales.

The WISDEM detector 10 has a very compact design. Without the need for dedicated signal amplifiers, the WISDEM is a high-quality oscillator that is very sensitive to small input signals, enabling simultaneous encoding of both low-frequency EEG signals and high-frequency MRI signals onto the same oscillation carrier wave. The encoded signals appear as distinct sidebands that are easily separable in the frequency domain. Because EEG and MRI signals are retrieved from the same wireless carrier wave that can be detected by a standard MRI coil, no dedicated hardware is required to synchronize these two detection modalities. The WISDEM transducer consists of two nonlinear circuits that can be individually optimized, i.e., the Voltage Sensing Resonator (VSR) for low-frequency signal encoding and the Parametric Resonator (PR) for high-frequency signal encoding and wireless carrier broadcasting. The PR has a circular mode and a butterfly mode to sustain oscillating current flows. The PR can utilize wireless pumping power provided at the sum frequency of its two resonance modes and the multi-band frequency mixing process to provide power for circuit oscillation at the circular and butterfly modes. On the other hand, the voltage sensing resonator is made by connecting the emitter and collector terminals of a Bipolar Junction Transistor with an 8-shaped conductor wire. Unlike the previous design that used two varactor diodes in head-to-head configuration, the voltage sensing resonator used here has an inductor connected to a single-element transistor. Since only two soldering junctions instead of four are required to complete the resonance circuit, the VSR 50 has a higher quality factor (Q=75) with smaller parasitic resistance. When the neuronal voltage applied on the transistor's base varies over time, the emitter-base junction capacitance C_{eb} and the collector-base junction capacitance Ccb are varied at the same pace, leading to effective modulation of the VSR's resonance frequency. Also, because the transistor's terminals are connected to sensing electrodes via buffering resistors, radio-frequency noises from biological tissues are mostly blocked by the buffering resistors, thus minimizing circuit loss. When the VSR couples to the circular resonance mode of the PR, resonance frequency shift of the VSR can be efficiently converted into oscillation frequency shift of the PR, and the time-dependent oscillation signal can be wirelessly detected by a standard MRI coil with cable connection to the scanner console. Because both the PR and VSR have low circuit loss, the oscillation signal of the entire WISDEM transducer has a narrow linewidth (100 Hz), enabling efficient detection of low-frequency voltage signals as small as 18 μV. For high-frequency MRI signals, the PR can combine down conversion and frequency encoding into a single stage, thus modulating the oscillation signal at the offset frequency between the input signal and the oscillation signal. After derivatizing the phase angles of the oscillation signal, the MR signal corresponding to individual time points can be retrieved by high-pass filtering. Image reconstruction by 2D Fourier Transform can be correctly performed when each magnitude term HPF(dØₜ/dt) is multiplied by the phase factor exp(−jØₜ) of the oscillation signal.

Another advantage of the WISDEM is the transducer's signal encoding capability is minimally perturbed by imaging sequences. This is because MRI signals are received by the butterfly mode of the parametric resonator that is tuned approximately to the proton Larmor frequency. Because the butterfly mode of the Parametric Resonator (PR) has a magnetic field pattern that is perpendicular to the B₁ field produced by the volume coil, the excitation B₁ field from the volume coil has minimal interfering effect on the PR. This averts the need for specialized designs and fabrication of complicated electrodes or recording instruments that were traditionally required to minimize the noise contamination inside MRI scanners. Unlike previous work on simultaneous fMRI and EEG that required graphene electrodes to reduce electromagnetic artifacts propagating along connection cables, the WISDEM can interface with traditional metallic electrodes that are widely used in neuroscience labs. Because the WISDEM's oscillation signal is continuously recorded over the entire duration of MR acquisition windows even in the presence of rapidly switching gradients, fMRI and EEG signals can be reliably retrieved using the simple method described in FIG. 3 and FIGS. 11A-K. These desirable features make it convenient to perform synchronous measurement of neuronal and hemodynamic activities in both healthy and diseased animals for mechanistic studies of neurovascular coupling/decoupling.

In addition to observing focal regions that are closer to the brain surface, there is a high demand to monitor neuronal activation in deep-lying regions across the entire brain. In our prototype device, the parametric resonator has a diameter of 13.5 mm, creating a butterfly mode with an effective detection depth of ˜10 mm that is already comparable to the radius of a rat brain. To further enlarge the detector's effective depth, the circular mode of the parametric resonator was potentially used to receive MR signals from deeper regions and align the detector's normal axis perpendicular to the B₁ field of a linear-mode volume coil that will be utilized for nuclear spin excitation. Such an arrangement can fully utilize the detection depth of a circular-mode detector and at the same time minimize interfering interactions from the MR excitation pulses, leaving the residual interference easily removable by the baseline correction algorithm described in FIGS. 11A-K. To record neuronal activity from different brain layers, it is possible to detect individual layers by multiple electrodes and connect all electrodes to the same Voltage Sensing Resonator via a multiplexer. As a result, the same detector can consecutively encode neuronal voltages from multiple electrodes while continuously encoding MRI signals from the same field-of-view. To simultaneously detect multiple brain regions over an extended FOV, it is also possible to construct multiple WISDEM detectors, each of which is wirelessly activated by a unique pumping frequency, enabling independent manipulation of individual detectors. Besides EEG encoding, the wirelessly powered oscillator can significantly improve the spatiotemporal detectability of tiny resonance frequency shifts induced by multiple types of physiological parameters providing a paradigm-shift concept in sensor design.

A wirelessly powered oscillator that can encode both low-frequency and high-frequency signals for simultaneous EEG and fMRI is set forth. Without the need for cable connection to a separate EEG apparatus, this multi-modal transducer can be easily mounted onto headpost of live animals required for chronic fixation of implantable optical fibers, thus facilitating the use of concurrent fiber photometry during simultaneous EEG/fMRI.

All procedures herein were conducted in accordance with guidelines set by the Institutional Animal Care and Use Committee of Michigan State University. In total 10 Sprague Dawley rats (1 rat for control experiment without AAV-ChR2-mCherry, 5 for forepaw stimulation experiments and 4 for optogenetic-fMRI experiments) from Charles River were used in this study. All animals were three-in-one-housed in 12-12 hour on/off light-dark cycle conditions to assure undisturbed circadian rhythm and ad libitum access to food and water.

Optogenetic virus injection is performed may be performed. AAV5.CaMKII.hChR2 (H134R)-mCherry was purchased from Addgene and packaged into frozen-stored vials, each of which contained 100 μL of sample at a concentration higher than 1×10¹³ vg/mL. To inject AAV5 into the right somatosensory forepaw region of brain in a 4-week-old rat, the rat was first anesthetized with 1.5-2% isoflurane via a nose cone and secured on a stereotaxic frame. An incision was made on the scalp to expose the skull before craniotomies were made with a pneumatic drill to introduce minimal damage to cortical tissue. Afterwards, 0.4-0.6 μL of viral droplet was injected from a 10-μL syringe via a 35-gauge needle to the following coordinates: 0 mm posterior to the Bregma, 3.2-3.5 mm lateral to the midline, 0.5-1.2 mm below the cortical surface using an infusion pump (Pump 11 Elite, Harvard Apparatus, USA). Once AAV5 injection was finished, the needle was left in place for approximately 5 min before being slowly pulled out. The craniotomies were sealed with bone wax, and the skin around the wound was sutured. After the surgery, rats were subcutaneously injected with antibiotics and painkillers (Ketoprofen fluids) for three consecutive days to prevent infection and to relieve pain. Imaging experiments were performed 4 weeks after virus injection to allow enough ChR2 protein expression in the S1FP region.

Animal preparation, electrode and fiber implantation may be performed. To prepare for electrode implantation, an enameled copper wire of 80-μm diameter was glued with an optical fiber of 200-μm core diameter (FT200EMT, Thorlabs). The front edge of the copper wire was trimmed by a scissor to expose the conductor tip for direct contact with the brain tissue. Once the animal was anesthetized by 2% isoflurane with its head fixed on a stereotaxic frame, a burr hole of 1.5-mm diameter was drilled on the rat's skull so that the dura can be carefully removed. Afterwards, the optical fiber along with the attached electrode was inserted into the S1FP region, at coordinates of 0 mm posterior to Bregma, 3.2-3.5 mm lateral to the midline and 1.2 mm below the cortical surface. Subsequently, an adhesive gel (Loctite 454, Henkel, Germany) was applied on the insertion hole to secure the fiber/electrode assembly against the skull. A grounding electrode was separately screwed against the skull above the neck. After the scalp was closed by glue, the rat was injected by a bolus of dexmedetomidine (0.05 mg/kg, sc; Dexdomitor®, Orion Pharma) before isoflurane was discontinued. The rat was then transferred into the MR scanner with its head secured by a bite bar and two ear bars, so that the WISDEM detector could be mounted above the rat's head to cover the right S1FP region (FIG. 4A). Finally, both the sensing electrode and the grounding electrode were connected to the plug-in pins that were previously soldered on the voltage sensing resonator.

During in vivo imaging, the rat was subcutaneously administered with constant infusion of dexmedetomidine at 0.1 mg/kg/hr. Its breathing and heart rates were monitored by an air pillow placed beneath its chest that was interfaced with an MR-compatible monitoring system (Model 1025, SA Instruments, Inc., Stony Brook, NY). The rat's body temperature was continuously monitored by a rectal probe (SA instrument) and maintained at 37° C. by a water jacket.

Functional MRI acquisition is described. All MRI data were acquired inside a 7T small-animal scanner (Bruker BioSpin, Billerica, MA) with a 16-cm horizontal bore. The WISDEM detector was placed above the animal's skull and activated by a loop antenna to produce sustained oscillation signal. Functional MR images were acquired with a multi-slice gradient-echo EPI (GE-EPI) sequence with the following parameters: time of echo (TE)=20.381 ms, time of repetition (TR)=1 s, field of view (FOV)=78×26×14.4 mm³, matrix size=129×43, voxel size=0.6×0.6 mm², slice number=24, flip angle=90°, bandwidth=326087 Hz. Concurrently during image acquisition, electrical stimulation was also performed on the rat's left forepaw or optogenetic stimulation in the S1FP region. For both the forepaw and optogenetic stimulation, the stimulation paradigm started from a 15-s pre-stimulation delay, followed by 8 epochs of stimulation cycles, each of which starts from a 2-s resting period followed by 4-s stimulation period and concludes by a 9-s interval. As a result, the total repetition number for the entire EPI experiment was 135. The 4-s period for electrical forepaw stimulation contained 20 biphasic pulses, each of which had 333-μs duration and 5-Hz repetition rate. The 4-s period for optogenetic stimulation contained 20 square pulses, each of which had 10-ms duration and 5-Hz repetition rate.

MRI data analysis is described. After functional images were retrieved using the algorithm described in FIGS. 3A and 11A-11K, were imported into the AFNI software (Analysis of Functional Neurolmages, NIH, USA) for subsequent analysis. First, functional images were aligned to anatomical images that were separately acquired with RARE (Rapid Acquisition with Relaxation Enhancement) sequence. These anatomical images had the same orientation and FOV as functional images but with a higher spatial resolution at 100 μm. The anatomical images were then registered to SIGMA rat brain template to derive the transformation relation, based on which the functional EPI images were registered to the same standard template. The baseline signal of EPI images was normalized to 100 for statistical analysis of multiple trials over the time course. The time courses of the BOLD signal were extracted from the S1FP region because this region had significant activation values in the brain atlas. The hemodynamic response function (HRF) was obtained by the linear program 3dDeconvolve in AFNI, where the statement BLOCK (L, 1) represented convolution with a square wave of duration L and peak amplitude of 1. To compute the evoked BOLD changes in FIGS. 4D, 5Gg, 5i-5l, 3dmaskave was executed on the ROI defined as the primary somatosensory area in the SIGMA atlas.

Immunohistochemistry is described. To verify the phenotype of the transfected cells, opsin localization, and optical fiber placement, the rat was sacrificed and perfused in its left ventricle. The rat brain was extracted, fixed overnight in 4% paraformaldehyde and then equilibrated overnight in 15% sucrose dissolved in 0.1 M phosphate buffer at 4° C., before being soaked inside 30% sucrose dissolved in 0.1 M phosphate buffer. Subsequently, the brain was sectioned to 30-μm slices on a sliding microtome (Leica CM 1850, Germany). Free-floating brain slices were washed in PBS, mounted on microscope slides, and incubated with DAPI (Sigma Aldrich, USA) at room temperature, before being imaged by a fluorescent microscope (Nikon A1 Laser Scanning Confocal Microscope, Japan) for assessment of ChR2 expression in the S1FP region as in FIG. 5A. To enhance brightness and contrast for visualization purposes, digital images were minimally processed using ImageJ.

The parametric resonator uses an externally provided pumping signal to oscillate. Normally, the pumping frequency ωₚ can be experimentally adjusted by tuning the knob of an external frequency synthesizer. Once ωₚ is set, it will also determine the sum of butterfly and circular mode oscillation frequencies, i.e., ωₚ=ω_{b}+ω_{c}. The exact values of ω_{b} and ω_{c} can be derived from the following equation that describes the equal relation of reactance-to-resistance ratio in both resonance modes:

$$\frac{{X}_{b}}{{R}_{b}} = \frac{2 ( {ω}_{b} - {ω}_{br} ) {L}_{b}}{{R}_{b}} = 2 ( \frac{{ω}_{b}}{{ω}_{br}} - 1 ) {Q}_{b} = \frac{{X}_{c}}{{R}_{c}} = \frac{2 ( {ω}_{C} - {ω}_{cr} ) {L}_{C}}{{R}_{C}} = 2 ( \frac{{ω}_{C}}{{ω}_{cr}} - 1 ) \qquad ( 1 )$$

In Eq. (1), L_{b} and L_{c} are effective inductance of the butterfly and circular modes, while R_{b} and R_{c} are effective resistance of the butterfly and circular modes. By plugging ω_{b}=ωₚ−ω_{c} into Eq. (1), the butterfly mode oscillation frequency can be calculated as:

$${ω}_{b} = \frac{{L}_{C} {R}_{b} {ω}_{p} + {L}_{b} {R}_{C} {ω}_{br} - {L}_{C} {R}_{b} {ω}_{cr}}{{L}_{C} {R}_{b} + {L}_{b} {R}_{C}} \qquad ( 2 )$$

If a voltage sensing resonator can somehow modulate the circular mode resonance frequency ω_{cr} without affecting the butterfly mode resonance frequency ω_{br}, the value of ω_{b} can also be effectively modulated.

In FIGS. 6A-6E, the reconstructed LFP traces obtained during optogenetic stimulation of a representative rat under different light power are set forth. Stimulation pulses were applied at 0.2, 0.4, 0.6, 2.2, 2.4, 2.6, 4.2, 4.4, 4.6, 6.2, 6.4, 6.6, 8.2, 8.4, 8.6, 10.2, 10.4, 10.6, 12.2, 12.4, 12.6, 14.2, 14.4 and 14.6 seconds following the initial starting point of pulse sequence. The light lines in the right column show all the LFP traces after individual stimulation pulses, while the dark line represents the average value of lighter traces.

Referring now to FIGS. 7A-7E, the reconstructed LFP traces obtained during optogenetic stimulation of a representative rat using different light widths. Stimulation pulses were applied at 0.2, 0.4, 0.6, 2.2, 2.4, 2.6, 4.2, 4.4, 4.6, 6.2, 6.4, 6.6, 8.2, 8.4, 8.6, 10.2, 10.4, 10.6, 12.2, 12.4, 12.6, 14.2, 14.4, 14.6 seconds. The light lines in the right panel show all the LFP traces after individual stimulation pulses, while the darker lines represent the average value of lighter traces.

Referring now to FIGS. 8A-D, the reconstructed LFP traces obtained during optogenetic stimulation of a representative rat under different light power, showing the comparable peak intensity obtained in the absence (FIGS. 8A and 8D) and presence (FIGS. 8B and 8D) of RF and gradient pulses. When no RF or gradient pulses were present, the S1FP region was stimulated at 2-Hz every other second within a 15-s period to quickly verify the brain was in an arousal state to produce LFP signals. Subsequently, RF and gradient pulses were turned on for Echo Planar Imaging, while the S1FP region was stimulated by 8 epochs of stimulation cycles, each of which started from a 2-s resting period followed by a 4-s stimulation period containing 20 pulses applied at 5 Hz. Each stimulation cycle finally concluded by a 9-s interval. The lighter lines in the right panel show all individual LFP from the eight epochs, while the dark lines represent the average value of light traces.

Referring now to FIG. 9, when the same amount of maximum laser power was applied on a control rat without AAV-ChR2 expression, no LFP spikes were observed from the S1FP region, thus demonstrating the neuronal origin of LFP spikes in FIGS. 6A-E, 7A-D and 8A-D, rather than photoelectric effect.

Referring now to FIGS. 10A-10B, the reconstructed LFP traces obtained during forepaw stimulation of a representative rat under 1 mA in FIG. 10A and 2 mA in FIG. 10B. Individual stimulation pulses had widths of 333-μs. They were applied at 0.2, 0.4, 0.6, 2.2, 2.4, 2.6, 4.2, 4.4, 4.6, 6.2, 6.4, 6.6, 8.2, 8.4, 8.6, 10.2, 10.4, 10.6, 12.2, 12.4, 12.6 s. The light lines in the right column show all the LFP traces after individual stimulation pulses, while the dark line represents the average value of light traces.

Referring now to FIGS. 11A-K, to reconstruct EPI images for all the 24 slices, the oscillation signal of the detector 10 was recorded over the entire duration of the MR acquisition window. The phase Øₜ of oscillation signal was derivatized over time dØₜ/dt before being high pass filtered (HPF) to obtain the raw signal in FIG. 11A. The intense spikes appeared between adjacent slices due to acquisition discontinuity. They could be removed by medium filter, leading to cleaned k-space signal, as exemplified in FIG. 11B that corresponded to the 19-th slice during interlace acquisition shown by region in FIG. 11A. To minimize acquisition delays without reducing the effective echo time (TE), each k-space line was sampled during both positive and negative gradients, while the retrieved k-space signals for the positive and negative gradients were separated into FIG. 11C and FIG. 11D. For each point in the k-space, the amplitude signal HPF(dØₜ/dt) was multiplied by the phase term exp(−jØₜ) of the oscillation signal, leading to a phase-sensitive signal exp(−jØₜ)*HPF(dØₜ/dt) for that time point. This phase multiplication procedure was performed for both signals in FGIG 11C and FIG. 11D before 2D Fourier transformation was separately performed on both signals, leading to 2D images that were combined into a single image frame in FIG. 11E. To simultaneously retrieve EEG signals, the derivatized phase signal dØₜ/dt was low pass filtered, leading to raw EEG signal in FIG. 11F containing repetitive baseline variation pattern that was synchronized with individual slice acquisition. This baseline variation pattern was averaged over all the 24 slices. As shown in FIG. 11G, the average baseline pattern had 43 pairs of positive and negative peaks, corresponding to 43 k-space lines each of which contained one positive gradient slope and one negative gradient slope. By subtracting each baseline pattern in FIG. 11F with the average baseline in FIG. 11G multiplied by an empirical factor for optimal cancellation, the baseline corrected signal in FIG. IG 11H was obtained that only contained discontinuous spikes at the interface between adjacent acquisition windows. After applying a medium filter to remove spikes, the EEG signal showed up in FIG. 11I. To convert the horizontal coordinate from slice index in FIG. 11I into acquisition time, acquisition delays light stripes in FIG. 11J were incorporated between adjacent acquisition windows. The EEG value during each acquisition delay was estimated as the average value before and after this delay, leading to continuous EEG pattern. As shown in FIG. 11K, all optogenetic stimulation pulses started at integral multiples of 0.2 s. The negative spike at ˜0.21 s had smaller intensity than other spikes, because part of this spike overlapped with the acquisition delay sandwiched between adjacent acquisition windows for individual slices.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A detector circuit comprising:
a parametric resonator circuit comprising a first varactor and a second varactor disposed in a loop, said parametric resonator comprising a conductor disposed between the first varactor and the second varactor; and
a voltage sensing resonator circuit is aligned on the parametric resonator circuit so that at least a first portion of the resonator circuit is disposed in the loop and a second portion is disposed outside the loop in an axial view.

2. The detector circuit of claim 1 further comprising an enhancer circuit disposed around the parametric resonator circuit and the voltage sensing resonator circuit.

3. The detection circuit of claim 2 wherein the enhancer circuit comprises a trim capacitor.

4. The detector circuit of claim 2 wherein the enhancer circuit comprises a one loop coil disposed around the parametric resonator circuit.

5. The detector circuit of claim 1 wherein the parametric resonator comprises a loop-gap resonator.

6. The detector circuit of claim 1 wherein the conductor extends between a first anode of the first varactor and a second anode of the second varactor, and a first cathode of the first varactor and a second cathode of the second varactor.

7. The detector circuit of claim 6 wherein the first anode of the first varactor and the second anode of the second varactor are adjacent and the first cathode of the first varactor and the second cathode of the second varactor are adjacent.

8. The detector circuit of claim 1 wherein the wherein the voltage sensing resonator circuit comprises a first coil around a first rod and a second coil disposed around a second rod.

9. The detector circuit of claim 8 wherein the parametric resonator circuit is disposed partially between the first rod and the second rod.

10. The detector circuit of claim 9 wherein the first coil and the second coil are formed of a continuous conductor wrapped in opposite directions around the first rod and the second rod.

11. The detector circuit of claim 10 further comprising a transistor comprising an emitter, a base and a collector, said emitter coupled to a first end of the continuous conductor and the base coupled to a second end of the continuous conductor.

12. The detector circuit of claim 11 wherein the transistor comprises a bipolar junction transistor.

13. The detector circuit of claim 11 further comprising a first resistor coupled between the base and the emitter.

14. The detector circuit of claim 13 further comprising a second resistor coupled to a first end of the first resistor and the emitter, and a third resistor coupled to a second end of the first resistor and the base.

15. The detector circuit of claim 1 wherein the voltage sensing resonator circuit comprises an inductor loop.

16. The detector circuit of claim 15 wherein the inductor loop is coupled to a transistor comprising an emitter, a collector, and base, said emitter coupled to a first end of the inductor loop and said collector coupled to a second end of the inductor loop.

17. The detector circuit of claim 16 further comprising a plurality of switches electrically couple to the inductor loop.

18. The detector circuit of claim 17 wherein the plurality of switches is controlled by a plurality of phototransistors or a plurality of photoresistors.

19. The detector circuit of claim 1 wherein a parametric resonator circuit comprises a first resonance mode and a second resonance mode.

20. A detector circuit comprising:
a parametric resonator circuit comprising a first varactor disposed in a first loop, said parametric resonator comprising a first conductor disposed between a first anode of the first varactor and a first cathode of the first varactor;
a voltage sensing resonator circuit is aligned on the parametric resonator circuit; and
an enhancer circuit disposed around the parametric resonator circuit and the voltage sensing resonator circuit.

21. The detector circuit of claim 20 wherein the parametric resonator circuit comprises a second varactor disposed in a second loop, said parametric resonator comprising a second conductor disposed between a second anode of the second varactor and a second cathode of the second varactor.

22. The detector circuit of claim 21 wherein the enhancer circuit comprises a trim capacitor or a fixed capacitance capacitor.

23. A detector circuit comprising:
a parametric resonator and enhancement circuit comprising a first varactor, a second varactor disposed and a capacitor in a loop, said parametric resonator comprising a first conductor coupled to a first node between the first varactor and the capacitor, a second conductor coupled to a second node between the second varactor and the capacitor, and a third conductor coupled to a third node between the first varactor and the second varactor; and
a voltage sensing resonator circuit is aligned on the parametric resonator circuit.

24. The detector circuit of claim 23 wherein the capacitor comprises a static capacitor or a trim capacitor.

25. The detector circuit of claim 23 wherein the wherein the voltage sensing resonator circuit comprises a first coil around a first rod and a second coil disposed around a second rod, said parametric resonator circuit is disposed partially between the first rod and the second rod, said first coil and the second coil are formed of a continuous conductor wrapped in opposite directions around the first rod and the second rod.

26. The detector circuit of claim 25 further comprising a transistor comprising an emitter, a base and a collector, said emitter coupled to a first end of the continuous conductor and the collector coupled to a second end of the continuous conductor.

27. The detector circuit of claim 15 wherein the voltage sensing resonator circuit comprises an inductor loop coupled to a transistor comprising an emitter, a collector, and base, said emitter coupled to a first end of the inductor loop and said collector coupled to a second end of the inductor loop, a plurality of switches electrically coupled to the inductor loop.

28. The detector circuit of claim 27 wherein the plurality of switches is controlled by a plurality of phototransistor or a plurality of photoresistors.
